(19) United States
(12) Patent Application Publication
(10) Pub. No.: US 2026/0065956 A1
(43) Pub. Date: Mar. 5, 2026

(54) SEMICONDUCTOR MEMORY DEVICE

(71) Applicant: Samsung Electronics Co., Ltd., Suwon-si (KR)

(72) Inventors: Junhyoung KIM, Suwon-si (KR); Bumkyu KANG, Suwon-si (KR); Siwan KIM, Suwon-si (KR); Jiyoung KIM, Suwon-si (KR); Sehyung LEE, Suwon-si (KR); Sehoon LEE, Suwon-si (KR); Sukkang SUNG, Suwon-si (KR)

(73) Assignee: Samsung Electronics Co., Ltd., Suwon-si (KR)

(21) Appl. No.: 19/227,746

(22) Filed: Jun. 4, 2025

(30) Foreign Application Priority Data
Sep. 3, 2024 (KR) 10-2024-0119517

(51) Int. Cl. G11C 5/10; G11C 16/04; H01L 23/00; H01L 25/18; H10B 12/00; H10B 43/10; H10B 43/27; H10B 43/35; H10B 43/40; H10B 80/00; H10D 80/30

(52) U.S. Cl. CPC G11C 5/10; G11C 16/0483; H10B 12/315; H10B 12/482; H10B 12/50; H10B 43/10; H10B 43/27; H10B 43/35; H10B 43/40; H10B 80/00; H10D 80/30

(57) ABSTRACT

A semiconductor memory device includes a mold structure including a plurality of gate electrodes, a gate electrode cutting pattern separating the mold structure into a plurality of blocks by cutting the plurality of gate electrodes along a plane, within a first block being at least one block among the plurality of blocks, a plurality of first capacitor structures penetrating the mold structure, a plurality of second capacitor structures penetrating the mold structure within the first block, a first capacitor connection structure on the first block, and connected to the plurality of first capacitor structures, and a second capacitor connection structure on the first block, is connected to the plurality of second capacitor structures. A first signal line connected to the first capacitor connection structure and a second signal line connected to the second capacitor connection structure are electrically separated.

### CROSS-REFERENCE TO RELATED APPLICATIONS

This application claims the benefit of Korean Patent Application No. 10-2024-0119517, filed on Sep. 3, 2024, in the Korean Intellectual Property Office, the disclosure of which is incorporated herein by reference in its entirety.

### BACKGROUND

Some example embodiments relate to a semiconductor memory device.

As semiconductor memory devices capable of storing large amounts of data are required in electronic systems, methods to increase the data storage capacity of semiconductor memory devices are being studied. As one of the methods to increase the data storage capacity of semiconductor memory devices, a semiconductor memory device is being proposed that includes three-dimensionally arranged memory cells instead of two-dimensionally arranged memory cells.

As the input/output speed of semiconductor memory devices continues to increase, more precise control of signal noise is desirable. Input/output speed can be increased by removing signal noise using high-capacity capacitors.

### SUMMARY

Some example embodiments may provide a semiconductor memory device by which the quality of input/output signals is improved.

Alternatively or additionally, some example embodiments may provide a semiconductor memory device by which input/output speed is improved.

However, the goals to be achieved by some example embodiments are not limited to the technical aspects described above, and other goals may be inferred from the following example embodiments.

According to some example embodiments, there is provided a semiconductor memory device including a mold structure including a plurality of gate electrodes stacked in a first direction, a gate electrode cutting pattern separating the mold structure into a plurality of blocks by cutting the plurality of gate electrodes along a plane including the first direction and a second direction intersecting the first direction, within a first block, the first block being at least one block among the plurality of blocks, a plurality of first capacitor structures penetrating the mold structure in the first direction, a plurality of second capacitor structures penetrating the mold structure in the first direction and within the first block, a first capacitor connection structure on the first block and connected to the plurality of first capacitor structures, and a second capacitor connection structure on the first block and connected to the plurality of second capacitor structures. A first signal line connected to the first capacitor connection structure and a second signal line connected to the second capacitor connection structure are electrically separated.

Alternatively or additionally according to some example embodiments, there is provided a semiconductor memory device including a mold structure including a plurality of gate electrodes stacked in a first direction, a gate electrode cutting pattern extending along a plane including the first direction and a second direction intersecting the first direction, the gate electrode cutting pattern separating the mold structure into a plurality of blocks by cutting the plurality of gate electrodes, a plurality of first capacitor structures penetrating the mold structure within a first block, the first block being at least one block among the plurality of blocks, a first electrode connecting structure penetrating the mold structure with in the first block and connected the plurality of gate electrodes, a plurality of second capacitor structures penetrating the mold structure within a second block spaced apart from the first block with the gate electrode cutting pattern in between, and along a third direction intersecting the first direction and the second direction among the plurality of blocks, a second electrode connecting structure penetrating the mold structure within the second block and connected the plurality of gate electrodes, and a capacitor connection structure on the mold structure in the first direction, and connected to the plurality of first capacitor structures and the plurality of second capacitor structures.

Alternatively or additionally, there is provided a semiconductor memory device including a cell substrate including a first substrate and a second substrate opposite to the first substrate, a mold structure including a plurality of gate electrodes stacked on the first substrate in a first direction perpendicular to the first substrate, a gate electrode cutting pattern extending along a plane including the first direction and a second direction intersecting the first direction, and separating the mold structure into a plurality of blocks by cutting the plurality of gate electrodes, a plurality of first capacitor structures penetrating the mold structure within a first block, the first block being at least one block among the plurality of blocks, a first electrode connecting structure penetrating the mold structure with in the first block and connect the plurality of gate electrodes, a first capacitor connection structure on the first block on the second substrate, and connected to the plurality of first capacitor structures, a plurality of second capacitor structures penetrating the mold structure within a second block spaced apart from the first block with the gate electrode cutting pattern in between, along a third direction intersecting the first direction and the second direction, and from among the plurality of blocks, a second electrode connecting structure penetrating the mold structure within the second block and connected to the plurality of gate electrodes, and a second capacitor connection structure on the second block on the second substrate, and connected to the plurality of second capacitor structures.

Additional aspects of some example embodiments will be set forth in part in the description which follows and, in part, will be apparent from the description, or may be learned by practice of some example embodiments.

According to some example embodiments, it may possible to improve the quality of input/output signals of semiconductor memory devices.

Alternatively or additionally according to some example embodiments, it may be possible to improve the input/output speed of semiconductor memory devices.

### BRIEF DESCRIPTION OF THE FIGURES

These and/or other aspects, features, and advantages will become apparent and more readily appreciated from the following description of some example embodiments, taken in conjunction with the accompanying drawings of which:

FIG. 1 is a block diagram illustrating a semiconductor memory device according to some example embodiments;

FIG. 2 is a circuit diagram illustrating a semiconductor memory device according to some example embodiments;

FIG. 3 is a schematic layout drawing illustrating a semiconductor memory device according to some example embodiments;

FIG. 4 is a drawing illustrating an enlarged view of a portion P of FIG. 3 according to some example embodiments;

FIG. 5 is a drawing illustrating a cross-section taken along line A-A of FIG. 3 according to some example embodiments;

FIG. 6 is a drawing illustrating an enlarged portion R1 of FIG. 5 according to some example embodiments;

FIG. 7 is another drawing illustrating an enlarged portion R1 of FIG. 5 according to some example embodiments;

FIG. 8 is a drawing illustrating an enlarged portion R2 of FIG. 5 according to some example embodiments;

FIG. 9 is another drawing illustrating an enlarged portion R2 of FIG. 5 according to some example embodiments;

FIG. 10 is a drawing illustrating a cross-section taken along line B-B of FIG. 3 according to some example embodiments;

FIG. 11 is another drawing illustrating a cross-section taken along line B-B of FIG. 3 according to some example embodiments;

FIG. 12 is a drawing illustrating a cross-section taken along line C-C of FIG. 3 according to some example embodiments;

FIG. 13 is a drawing illustrating a cross-section taken along line D-D of FIG. 3 according to some example embodiments;

FIG. 14 is a drawing illustrating an enlarged portion P of FIG. 3 according to some example embodiments in order to describe a semiconductor memory device according to some other example embodiments;

FIG. 15 is a schematic layout drawing in order to describe a semiconductor memory device according to another example embodiment;

FIG. 16 is a drawing illustrating an enlarged portion P of FIG. 15 according to some example embodiments;

FIG. 17 is a drawing illustrating a cross-section taken along line A-A of FIG. 15 according to some example embodiments;

FIG. 18 is a drawing illustrating a cross-section taken along line C-C of FIG. 15 according to some example embodiments;

FIG. 19 is a schematic layout drawing to describe a semiconductor memory device according to some example embodiments;

FIG. 20 is a drawing illustrating an enlarged portion P of FIG. 19 according to some example embodiments;

FIG. 21 is a drawing illustrating a cross-section taken along line A-A of FIG. 19 according to some example embodiments;

FIG. 22 is a drawing illustrating a cross-section taken along line B-B of FIG. 19 according to some example embodiments;

FIG. 23 is another drawing illustrating a cross-section taken along line B-B of FIG. 19 according to some example embodiments;

FIG. 24 is another drawing illustrating a cross-section taken along line A-A of FIG. 19 according to some example embodiments;

FIG. 25 is a schematic layout diagram illustrating a semiconductor memory device according to some example embodiments;

FIG. 26 is a drawing illustrating an enlarged portion P of FIG. 25 according to some example embodiments;

FIG. 27 is a drawing illustrating a cross-section taken along line A-A of FIG. 25 according to some example embodiments;

FIG. 28 is a drawing illustrating a cross-section taken along line B-B of FIG. 25 according to some example embodiments;

FIG. 29 is a drawing illustrating an electronic system including a semiconductor memory device according to some example embodiments;

FIG. 30 is a perspective view to describe an electronic system including a semiconductor memory device according to some example embodiments; and

FIG. 31 is a drawing illustrating a cross-section taken along line I-I of FIG. 30 according to some example embodiments.

### DETAILED DESCRIPTION

Prior to the detailed description of example embodiments, terms or words used in the specification and claims should not be construed as limited to their common or dictionary meanings. Further, the terms or words should be interpreted with meaning and concept consistent with the technical idea of example embodiments based on the principle that inventors may appropriately define the concept of terms in order to explain their invention in a definite manner. Example embodiments described in this specification and the configurations shown in the drawings are only some example embodiments, and do not necessarily represent the entire technical ideas. Accordingly, there may be various equivalents and modifications that can replace them.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. The terms “have,” “may have,” “include,” and “may include” as used herein indicate the presence of corresponding features (for example, elements such as numerical values, functions, operations, or parts), and do not preclude the presence of additional features.

Further, in the following description, expressions such as an upper side, top, a lower side, bottom, a side, front and a back side are expressed based on the direction shown in the drawing. If the direction of the object changes, it may be expressed differently.

Hereinafter, some example embodiments of the present disclosure will be described in detail with reference to the accompanying drawings.

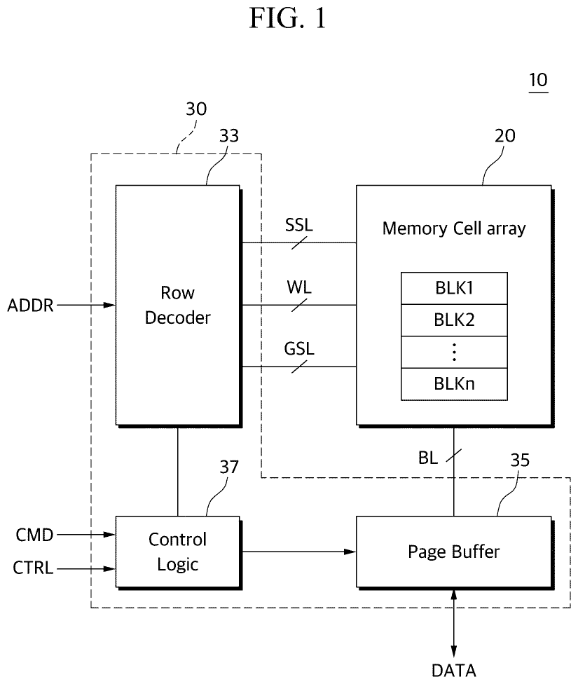

FIG. 1 is a block diagram illustrating a semiconductor memory device according to some example embodiments.

Referring to FIG. 1, a semiconductor memory device 10 may include a memory cell array 20 and a peripheral circuit 30.

According to some example embodiments, the memory cell array 20 may include multiple memory cell blocks (a first block BLK1 to an nth block BLKn). Each of the memory cell blocks (the first block BLK1 to the nth block BLKn) may include a plurality of memory cells, and may or may not include the same number of memory cell blocks. The memory cell array 20 may be connected to the peripheral circuit 30 through a bit line BL, a wordline WL, at least one string selection line SSL, and at least one ground selection line GSL. In some example embodiments, the memory cell blocks (the first block BLK1 to the nth block BLKn) may be connected to a row decoder 33 through the wordline WL, the string selection line SSL, and the ground selection line GSL. Further, the memory cell blocks (the first block BLK1 to the nth block BLKn) may be connected to a page buffer 35 through the bit line BL.

According to some example embodiments, the peripheral circuit 30 may receive one or more of an address ADDR, a command CMD and a control signal CTRL from outside of the semiconductor memory device 10, and may transmit and/or receive data DATA with a device external to the semiconductor memory device 10. The peripheral circuit 30 may include control logic 37, the row decoder 33, and the page buffer 35. Even though not illustrated, the peripheral circuit 30 may further include various sub-circuits, such as one or more of an input/output circuit, a voltage generation circuit that generates various voltages required for the operation of the semiconductor memory device 10, and an error correction circuit for correcting errors in data DATA read from the memory cell array 20.

According to some example embodiments, the control logic 37 may be connected to the row decoder 33, the input/output circuit and the voltage generation circuit. The control logic 37 may control the overall operation of the semiconductor memory device 10. The control logic 37 may generate various internal control signals used within the semiconductor memory device 10 in response to the control signal CTRL. For example, the control logic 37 may adjust levels such as the voltage levels or a magnitude of the voltage levels provided to the wordline WL, and the bit line BL when performing memory operations such as program or erase operations.

According to some example embodiments, the row decoder 33 may select at least one of multiple memory cell blocks (the first block BLK1 to the nth block BLKn) in response to the address ADDR, and the row decoder 33 may select at least one wordline WL, at least one string selection line SSL and at least one ground selection line GSL of selected memory cell blocks (the first block BLK1 to the nth block BLKn). In some example embodiments, the row decoder 33 may deliver voltage to the wordline WL of selected memory cell blocks (the first block BLK1 to the nth block BLKn) to perform memory operations.

According to some example embodiments, the page buffer 35 may be connected to the memory cell array 20 through the bit line BL. The page buffer 35 may operate as a writer driver or a sense amplifier. For example, when a program operation is performed, the page buffer 35 acts as a writer driver and may apply voltage to the bit line BL according to the data DATA to be stored in the memory cell array 20. Meanwhile, when performing a read operation, the page buffer 35 acts as a sense amplifier to detect data DATA stored in the memory cell array 20.

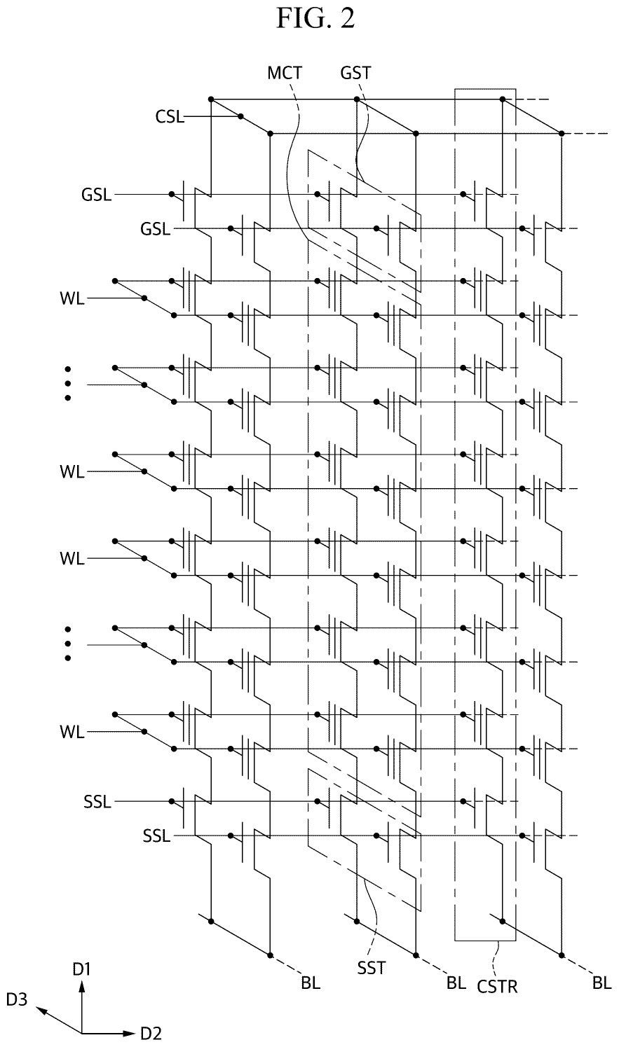

FIG. 2 is a circuit diagram illustrating a semiconductor memory device according to some example embodiments.

Referring to FIG. 2, a memory cell array of a semiconductor memory device (for example, the memory cell array 20 of FIG. 1) may include a common source line CSL, a plurality of bit lines BL, and a plurality of cell strings CSTR.

According to some example embodiments, the plurality of bit lines BL may be arranged two-dimensionally in a plane including the second direction D2 and the third direction D3. For example, each of the bit lines BL may extend in the third direction D3, and may be arranged along the second direction D2, spaced apart from each other. The plurality of cell strings CSTR may be connected in parallel to each of the bit lines BL. A cell string CSTR may be commonly connected to the common source line CSL. For example, the plurality of cell strings CSTR may be placed between the bit line BL and the common source line CSL. The plurality of cell strings CSTR may extend in the first direction D1.

According to some example embodiments, each cell string CSTR may include a ground selection transistor GST connected to the common source line CSL, a string selection transistor SST connected to the bit line BL and a plurality of memory cell transistors MCT placed between the ground selection transistor GST and the string selection transistor SST. Each memory cell transistor MCT may include a data storage element. The ground selection transistor GST, the string selection transistor SST, and the memory cell transistor MCT may be connected in series.

According to some example embodiments, the common source line CSL may be commonly connected to the sources of the ground selection transistors GST. Further, between the common source line CSL and the bit line BL, the ground selection line GSL, the multiple wordlines WL, and the string selection lines SSL may be placed. The ground selection line GSL may be used as the gate electrode of the ground selection transistor GST, the wordlines WL may be used as gate electrodes of the memory cell transistors MCT, and the string selection line SSL may be used as the gate electrode of the string selection transistor SST.

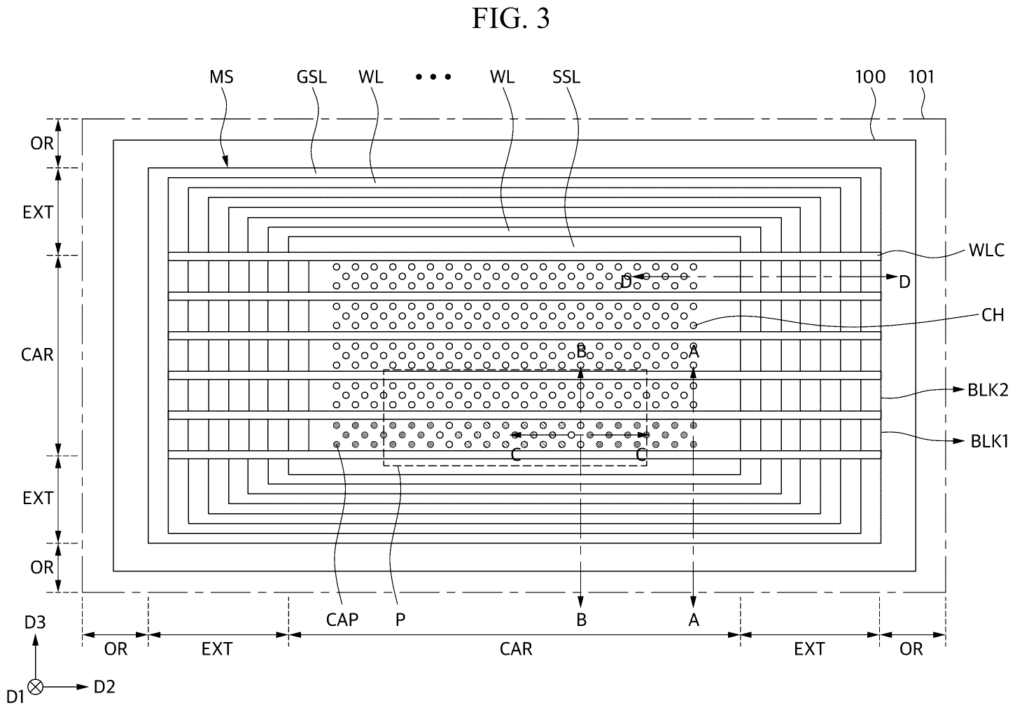

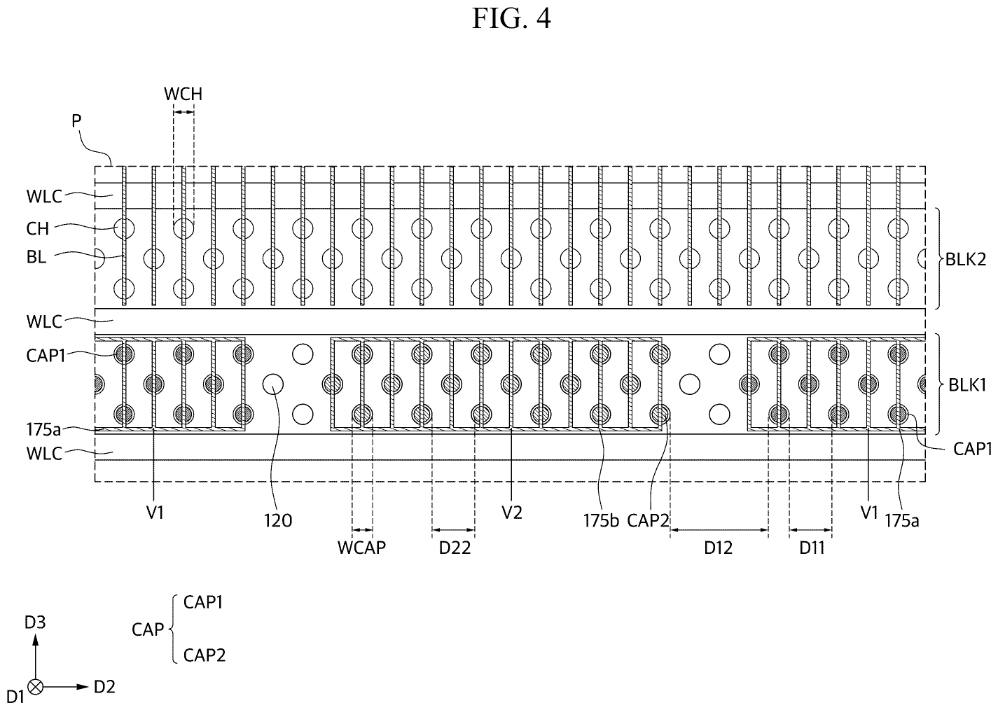

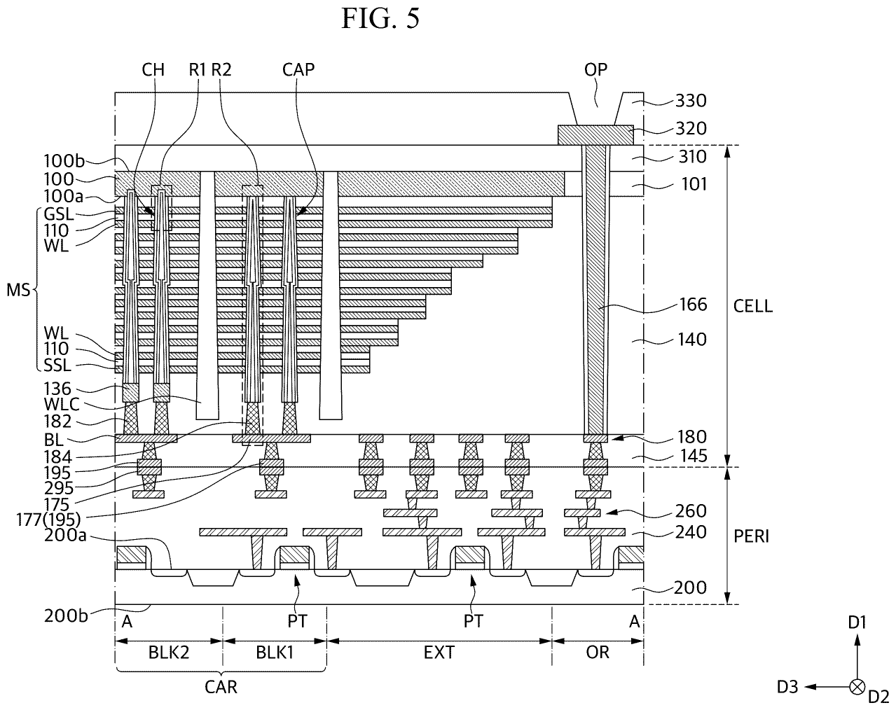

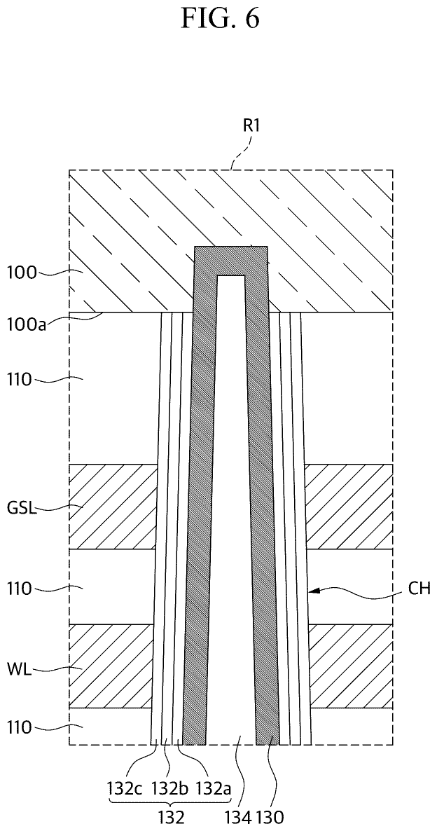

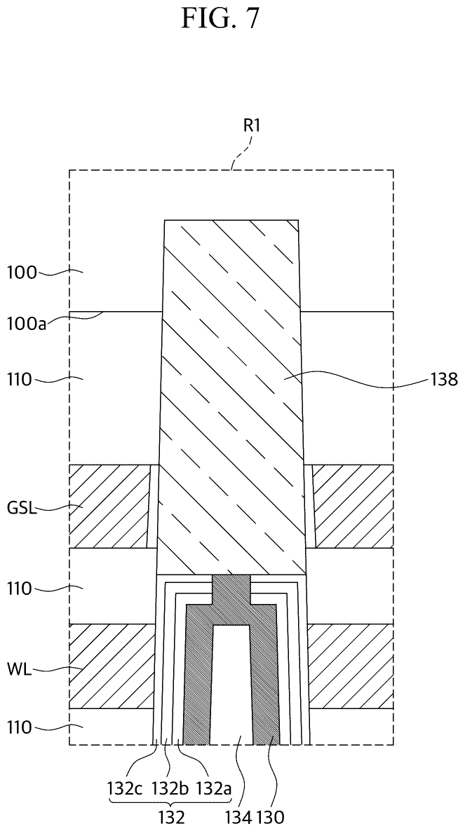

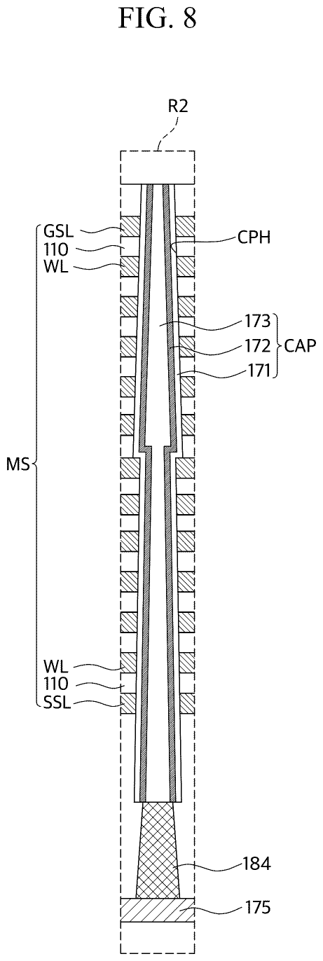

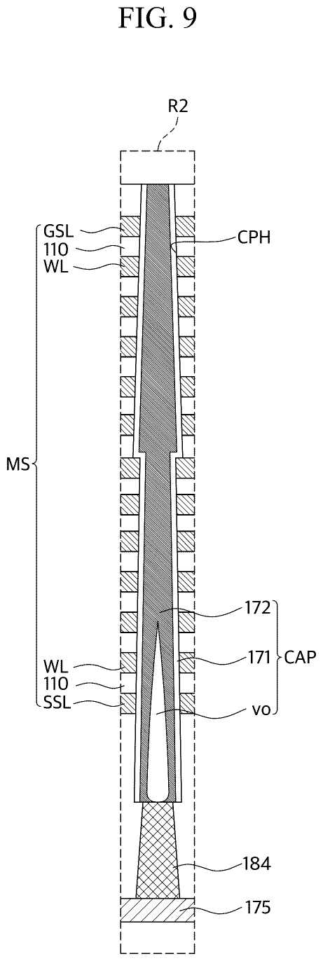

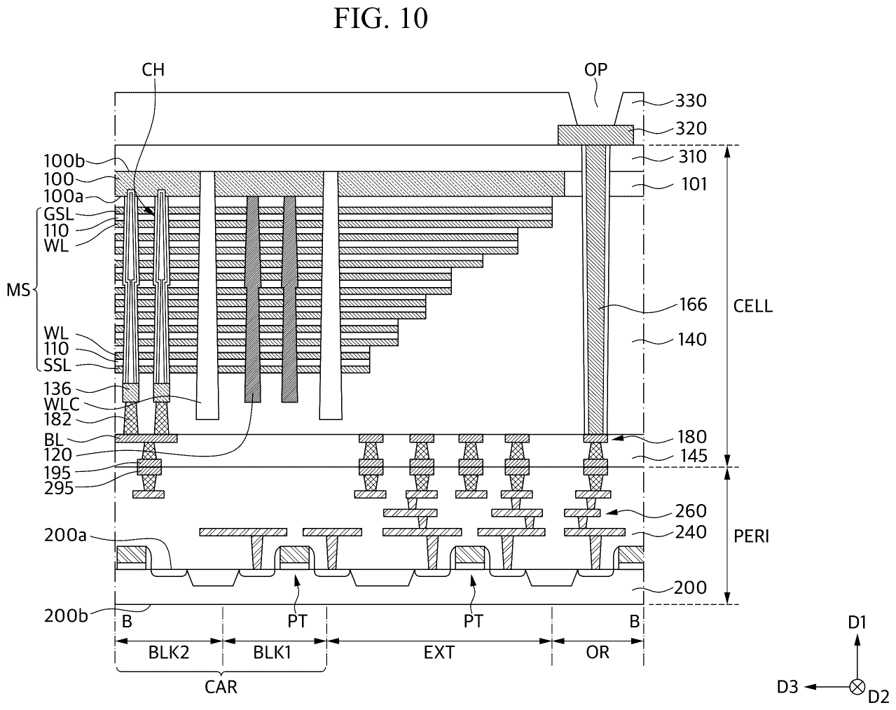

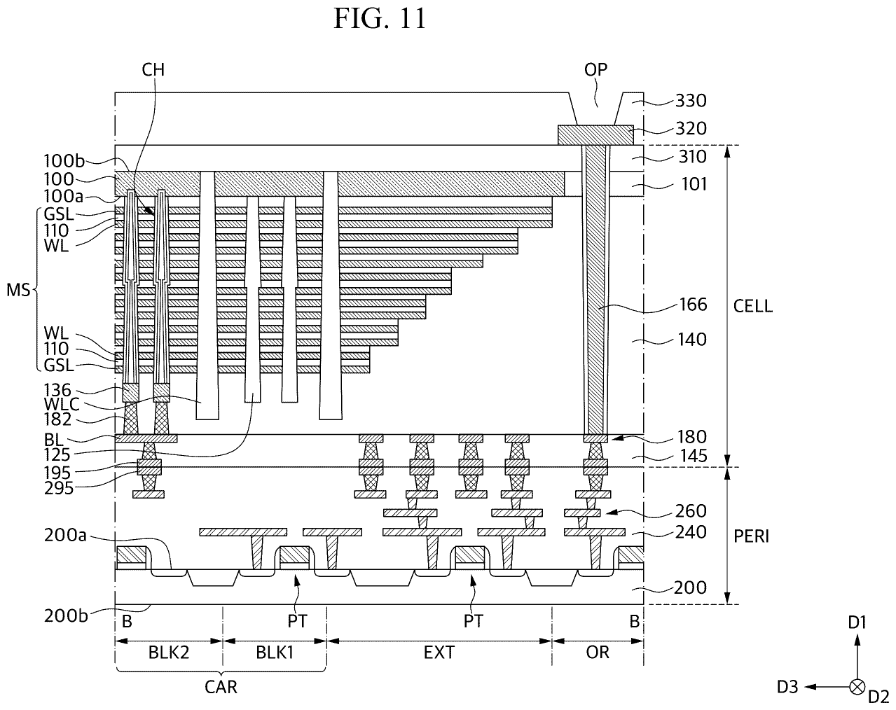

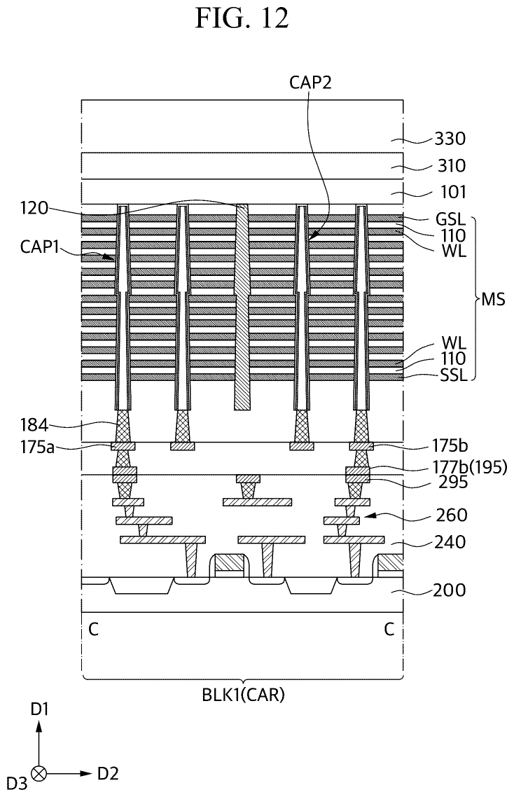

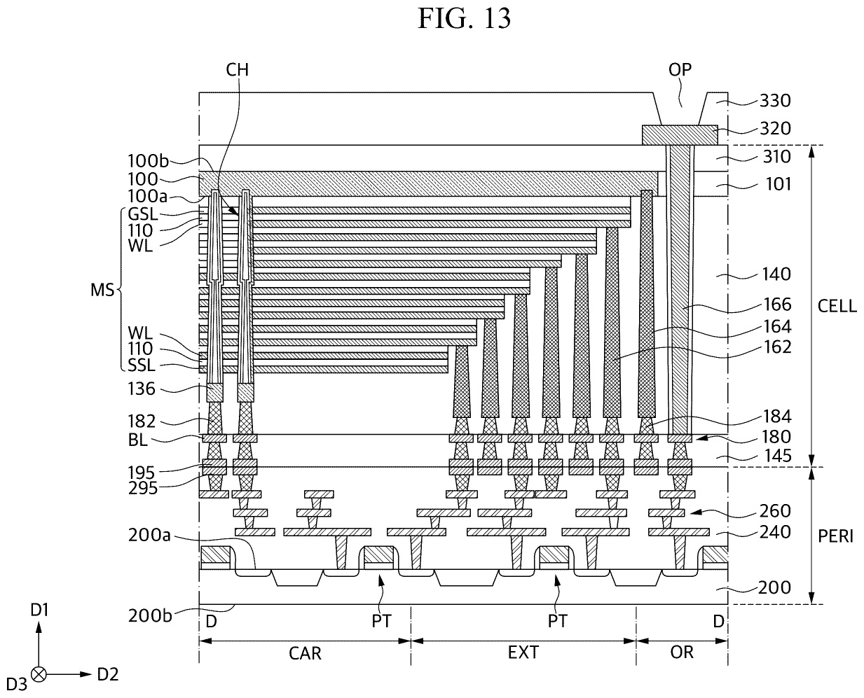

FIG. 3 is a schematic layout drawing illustrating a semiconductor memory device according to some example embodiments. FIG. 4 is a drawing illustrating an enlarged view of a portion P of FIG. 3 according to some example embodiments. FIG. 5 is a drawing illustrating a cross-section taken along line A-A of FIG. 3 according to some example embodiments. FIG. 6 is a drawing illustrating an enlarged portion R1 of FIG. 5 according to some example embodiments. FIG. 7 is another drawing illustrating an enlarged portion R1 of FIG. 5 according to some example embodiments. FIG. 8 is a drawing illustrating an enlarged portion R2 of FIG. 5 according to some example embodiments. FIG. 9 is another drawing illustrating an enlarged portion R2 of FIG. 5 according to some example embodiments. FIG. 10 is a drawing illustrating a cross-section taken along line B-B of FIG. 3 according to some example embodiments. FIG. 11 is another drawing illustrating a cross-section taken along line B-B of FIG. 3 according to some example embodiments. FIG. 12 is a drawing illustrating a cross-section taken along line C-C of FIG. 3 according to some example embodiments. FIG. 13 is a drawing illustrating a cross-section taken along line D-D of FIG. 3 according to some example embodiments.

Referring to FIG. 3 to FIG. 5, a semiconductor memory device according to some example embodiments may include a cell structure CELL and a peripheral circuit structure PERI.

According to some example embodiments, the cell structure CELL may include a cell substrate 100, an insulation substrate 101, a mold structure MS, a first interlayer insulating film 140, a gate electrode cutting pattern WLC, a channel structure CH, the bit line BL, a first capacitor structure CAP1, a second capacitor structure CAP2, a gate contact 162 and a cell wiring structure 180.

According to some example embodiments, the cell substrate 100 may be or may include a semiconductor substrate, such as, for example, one or more of a silicon substrate, a germanium substrate and a silicon-germanium substrate. Alternatively or additionally, the cell substrate 100 may be or may include a silicon-on-insulator (SOI) substrate or a germanium-on-insulator (GOI) substrate.

According to some example embodiments, the cell substrate 100 may contain impurities. For example, the cell substrate 100 may contain n-type impurities (for example, one or more of phosphorus (P), arsenic (As) and so on). However, the cell substrate 100 is not limited thereto. For example, the cell substrate 100 may alternatively or additionally contain P-type impurities such as but not limited to boron (B). The cell substrate 100 may include polysilicon (poly-Si) doped with N-type impurities and/or P-type impurities. The cell substrate 100 may be provided as a common source line (for example, the common source line CSL of FIG. 2) of a semiconductor memory device according to some example embodiments.

According to some example embodiments, the cell substrate 100 may include a cell array region CAR and an extended area EXT.

According to some example embodiments, a memory cell array (for example, the memory cell array 20 in FIG. 1) containing a plurality of memory cells may be formed in the cell array region CAR. For example, in the cell array region CAR, the channel structure CH, the bit line BL and a plurality of gate electrodes (the ground selection line GSL, the wordline WL, and the string selection line SSL) described later may be arranged. In example embodiments, a surface of the cell substrate 100 on which the above memory cell array is arranged may be referred to as a first substrate 100a of the cell substrate. The first substrate 100a of the cell substrate may be the front side of the cell substrate 100. Conversely, the surface of the cell substrate 100 opposite to the first substrate 100a of the cell substrate may be referred to as a second substrate 100b of the cell substrate. The second substrate 100b of the cell substrate may be the back side of the cell substrate 100.

According to some example embodiments, the gate electrode cutting pattern WLC may extend in the first direction D1. For example, the gate electrode cutting pattern WLC may extend along a plane including the first direction D1 and the second direction D2. The gate electrode cutting pattern WLC extends from the cell substrate 100 in the first direction D1, and may cut a plurality of gate electrodes (the ground selection line GSL, the wordline WL, and the string selection line SSL). The gate electrode cutting pattern WLC may cut a plurality of gate electrodes (the ground selection line GSL, the wordline WL, and the string selection line SSL) along a plane including a first direction D1 and a second direction D2 into a plurality of blocks. The gate electrode cutting pattern WLC may include at least one of an insulating material, for example, one or more of silicon oxide, silicon nitride and silicon oxynitride, but the gate electrode cutting pattern WLC is not limited thereto.

According to some example embodiments, the gate electrode cutting pattern WLC may extend in the second direction D2. The gate electrode cutting pattern WLC may extend across the cell array region CAR and the extended area EXT. For example, the gate electrode cutting pattern WLC may extend across the cell array region CAR and the extended area EXT adjacent to the cell array region CAR in the second direction D2.

According to some example embodiments, the gate electrode cutting pattern WLC may be spaced apart in the third direction D3. The gate electrode cutting pattern WLC may separate the mold structure MS into a plurality of blocks BLK1 and BLK2 in the third direction D3. The plurality of blocks BLK1 and BLK2 may be arranged in the third direction D3. The plurality of blocks BLK1 and BLK2 may include the first block BLK1 and the second block BLK2. The gate electrode cutting pattern WLC may be placed between the first block BLK1 and the second block BLK2. The gate electrode cutting pattern WLC may be placed between two adjacent second blocks BLK2. Each of the first block BLK1 and the second block BLK2 may be placed between two adjacent gate electrode cutting patterns WLC in the third direction D3.

According to some example embodiments, the mold structure MS may include the first block BLK1 and the second block BLK2. The first block BLK1 and the second block BLK2 may be arranged in the third direction D3. In the third direction D3, the first block BLK1 may be placed further outside the second block BLK2.

According to some example embodiments, the extended area EXT may be placed around the cell array region CAR. For example, the extended area EXT may surround the cell array region CAR in a planar view. In the extended area EXT, the plurality of gate electrodes (the ground selection line GSL, the wordline WL, and the string selection line SSL) described below may be stacked in a stepwise manner.

According to some example embodiments, the insulation substrate 101 may be formed around the cell substrate 100. The insulation substrate 101 may form an insulating region around the cell substrate 100. The insulation substrate 101 may include, for example, at least one of silicon oxide, silicon nitride, silicon oxynitride, and silicon carbide. However, the insulation substrate 101 is not limited thereto.

According to some example embodiments, the lower surface of the insulation substrate 101 may be coplanar with the first substrate 100a of the cell substrate, but it example embodiments are not limited thereto. Alternatively in some example embodiments, the lower surface of the insulation substrate 101 may be placed to be on a lower level than the first substrate 100a of the cell substrate.

According to some example embodiments, the cell substrate 100 and the insulation substrate 101 may further include an external area OR. The external area OR may be placed outside the cell array region CAR and the extended area EXT. For example, the external area OR may surround the cell array region CAR and the extended area EXT in a planar view. In the external area OR, a contact plug 166 described later may be placed.

According to some example embodiments, the mold structure MS may be formed on the first substrate 100a of the cell substrate. The mold structure MS may include a plurality of gate electrodes (the ground selection line GSL, the wordline WL, and the string selection line SSL) laminated on the cell substrate 100, and a plurality of mold insulating films 110. Each of the plurality of gate electrodes (the ground selection line GSL, the wordline WL, and the string selection line SSL) and each mold insulating film 110 may be a layered structure extending parallel to the first substrate 100a of the cell substrate. The plurality of gate electrodes (the ground selection line GSL, the wordline WL, and the string selection line SSL) may be sequentially laminated on the first substrate 100a of a cell substrate while being separated from each other by the mold insulating film 110. Even though it is illustrated that the plurality of gate electrodes (the ground selection line GSL, the wordline WL, and the string selection line SSL) include a single ground selection line GSL and a single string selection line SSL, some example embodiments thereon are not limited thereto. The plurality of gate electrodes (the ground selection line GSL, the wordline WL, and the string selection line SSL) include two or more ground selection lines and two or more string selection lines.

A thickness of each of the plurality of wordlines WL may be the same; alternatively, at least one of the plurality of wordlines WL may be thicker or thinner than at least one other of the plurality of wordlines WL. A thickness of each of the mold insulating films 110 may be the same and may or may not be the same as a thickness of a neighboring wordline WL; alternatively or additionally, at least one of the plurality of mold insulating films 110 may be thicker than or thinner than at least one other of the plurality of mold insulating films 110.

According to some example embodiments, the mold structure MS may include a first mold structure and a second mold structure that are sequentially laminated on the first substrate 100a of the cell substrate. The channel structure CH may have a bend between the first mold structure and the second mold structure. For example, a first mold structure may include first gate electrodes (the ground selection line GSL and the wordline WL) and the mold insulating film 110 alternately stacked on the cell substrate 100. In some example embodiments, the first gate electrodes (the ground selection line GSL and the wordline WL) may include the ground selection line GSL and the wordline WL sequentially laminated on the cell substrate 100. A second mold structure may include second gate electrodes (the wordline WL and the string selection line SSL) and the mold insulating film 110 alternately laminated on the first mold structure. In some example embodiments, the second gate electrodes (the wordline WL and the string selection line SSL) may include the wordline WL and the string selection line SSL that are sequentially laminated on the first mold structure.

According to some example embodiments, each of the plurality of gate electrodes (the ground selection line GSL, the wordline WL and the string selection line SSL) may include a conductive material, for example, one or more metals such as one or more of tungsten (W), cobalt (Co), nickel (Ni) and a semiconductor material such as silicon, e.g., doped polysilicon. However, the gate electrode is not limited thereto.

According to some example embodiments, the mold insulating film 110 may each contain an insulating material. For example, the mold insulating film 110 may include at least one of silicon oxide, silicon nitride and silicon oxynitride. However, the mold insulating film 110 is not limited thereto.

According to some example embodiments, the first interlayer insulating film 140 may be formed on the first substrate 100a and/or the insulation substrate 101 of the cell substrate to cover the mold structure MS. The first interlayer insulating film 140 may include, for example, at least one of silicon oxide, silicon oxynitride, and a low-k material having a lower dielectric permittivity than silicon oxide. However, the first interlayer insulating film 140 is not limited thereto.

According to some example embodiments, the channel structure CH may be formed within the mold structure MS of the cell array region CAR. The channel structure CH may extend in the first direction D1 perpendicular to the first substrate 100a of the cell substrate and penetrate the mold structure MS. The channel structure CH may be placed in the second block BLK2. The channel structure CH may penetrate the mold structure MS in the first direction D1 within the second block BLK2. For example, the channel structure CH may be a pillar shape (for example, a cylinder shape) extending in the first direction D1. Accordingly, the channel structure CH may intersect with each of the plurality of gate electrodes (the ground selection line GSL, the wordline WL, and the string selection line SSL). The channel structure CH may have a bend within the mold structure MS. For example, the channel structure CH may have a bend between the first mold structure and the second mold structure. The channel structure CH may have a step between the first mold structure and the second mold structure.

According to some example embodiments, the channel structure CH may be placed within a channel hole penetrating the mold structure MS. The channel hole may penetrate the mold structure MS on the first substrate 100a of the cell substrate. The channel structure CH may be arranged in a zigzag shape. For example, the channel structure CH may be arranged alternately in the second direction D2 and the third direction D3 parallel to the upper surface of the cell substrate 100. A plurality of channel structures CH arranged in a zigzag shape may further improve the integration density of semiconductor memory devices. The plurality of channel structures CH may be arranged in a honeycomb shape.

Referring to FIG. 6, the channel structure CH may include a semiconductor pattern 130 and an information storing film 132.

According to some example embodiments, the semiconductor pattern 130 may extend in the first direction D1 and intersect with the plurality of gate electrodes (the ground selection line GSL, the wordline WL, and the string selection line SSL). Even though it is illustrated that the semiconductor pattern 130 is cup-shaped, it is a mere example embodiment. For example, the semiconductor pattern 130 may have various shapes, such as a cylindrical shape, a square cylinder shape, and a solid filled shape. The semiconductor pattern 130 may include semiconductor materials such as, for example, one or more of single crystal silicon, polycrystalline silicon, organic semiconductors, and carbon nanostructures. However, the semiconductor pattern 130 is not limited thereto.

According to some example embodiments, the semiconductor pattern 130 may be connected to the cell substrate 100. For example, one end (for example, a top end) of the semiconductor pattern 130 may be exposed from the information storing film 132 and connected to the cell substrate 100. In some example embodiments, the semiconductor pattern 130 may penetrate the first substrate 100a of the cell substrate 100. For example, one end (for example, the top end) of the semiconductor pattern 130 may protrude beyond the information storing film 132. The semiconductor pattern 130 may improve contact resistance by increasing the contact area with the cell substrate 100.

According to some example embodiments, the information storing film 132 may be interposed between the semiconductor pattern 130 and each gate electrode (the ground selection line GSL, the wordline WL, and the string selection line SSL). For example, the information storing film 132 may extend along the outer side of the semiconductor pattern 130. The information storing film 132 may include, for example, at least one of silicon oxide, silicon nitride, silicon oxynitride, and a high dielectric material having a higher dielectric permittivity than silicon oxide. The high dielectric material may include at least one of, for example, aluminum oxide, hafnium oxide, lanthanum oxide, tantalum oxide, titanium oxide, lanthanum hafnium oxide, lanthanum aluminum oxide, dysprosium scandium oxide, and combinations thereof.

According to some example embodiments, the information storing film 132 may be formed into a multilayer film. For example, as illustrated in FIG. 6, the information storing film 132 may include a tunnel insulting film 132a, a charge storing film 132b, and a blocking insulting film 132c, which are sequentially laminated on the outer side of the semiconductor pattern 130.

According to some example embodiments, the tunnel insulting film 132a may include, for example, one or more of silicon oxide or a high dielectric material (for example, aluminum oxide (Al2O3), hafnium oxide (HfO2) and so on) having a dielectric permittivity higher than silicon oxide. For example, the charge storing film 132b may include silicon nitride. For example, the blocking insulting film 132c may include silicon oxide or a high dielectric material having a dielectric permittivity higher than silicon oxide (for example, one or more of aluminum oxide (Al2O3), hafnium oxide (HfO2) and so on).

According to some example embodiments, the channel structure CH may further include a filling insulation film 134; however, example embodiments are not limited thereto. The filling insulation film 134 may be formed to fill the interior of the cup-shaped semiconductor pattern 130. The filling insulation film 134 may include an insulating material, for example, silicon oxide, but the filling insulation film 134 is not limited thereto.

Referring to FIG. 7, the channel structure CH may further include a source pattern 138. The source pattern 138 may be formed on the cell substrate 100. The source pattern 138 may be connected to the semiconductor pattern 130. For example, the semiconductor pattern 130 may penetrate the information storing film 132 and come into contact with the source pattern 138. The source pattern 138 may include a conductive material, for example, polysilicon such as doped polysilicon and/or a metal doped with impurities. However, the source pattern 138 is not limited thereto. The source pattern 138 and the cell substrate 100 may be provided as a common source line of a semiconductor memory device (for example, the common source line CSL of FIG. 2).

In some example embodiments, the source pattern 138 may be an epitaxial pattern, e.g., a pattern formed from epitaxially the cell substrate 100 by a selective epitaxial growth process. There may or may not be a seem or interface between the cell substrate 100 and the source pattern 138; example embodiments are not limited thereto.

Referring back to FIG. 3 to FIG. 5, the channel structure CH may further include a channel pad 136. The channel pad 136 may be formed to be connected to the other end (for example, bottom) of the semiconductor pattern 130. The channel pad 136 may include a conductive material, for example, doped polysilicon or a metal. However, the channel pad 136 is not limited thereto.

According to some example embodiments, the bit line BL may be formed on the mold structure MS. The bit line BL may be extended in the third direction D3 and intersect the gate electrode cutting pattern WLC. Further, the bit line BL may extend in the third direction D3 and connected to multiple channel structures CH arranged along the third direction D3. For example, a bit line contact 182 may be formed within the first interlayer insulating film 140 to connect to the upper portion of each channel structure CH. The bit line BL may be electrically connected to the channel structure CH through the bit line contact 182.

According to some example embodiments, a capacitor structure CAP may be placed in the first block BLK1. The capacitor structure CAP may include a plurality of first capacitor structures CAP1 and a plurality of second capacitor structures CAP2. The plurality of first capacitor structures CAP1 and the plurality of second capacitor structures CAP2 may penetrate the mold structure MS within the first block BLK1.

According to some example embodiments, the plurality of first capacitor structures CAP1 and the plurality of second capacitor structures CAP2 may be placed within one first block BLK1. The plurality of first capacitor structures CAP1 and the plurality of second capacitor structures CAP2 may be arranged in the second direction D2 within the first block BLK1. For example, the plurality of first capacitor structures CAP1 and the plurality of second capacitor structures CAP2 may be arranged spaced apart in the second direction D2. An electrode connecting structure 120 may be placed between the plurality of first capacitor structures CAP1 and the plurality of second capacitor structures CAP2.

According to some example embodiments, a distance between two of the plurality of first capacitor structures CAP1 adjacent to each other in the second direction D2 and the distance between two of the plurality of second capacitor structures CAP2 adjacent to each other in the second direction D2 may be shorter than a distance between one first capacitor structure CAP1 and one second capacitor structure CAP2, which are adjacent to each other in the second direction D2. For example, the first distance D11 between two of the plurality of first capacitor structures CAP1 adjacent to each other in the second direction D2 and the second distance D22 between two of the plurality of second capacitor structures CAP2 adjacent to each other in the second direction D2 may be shorter than the third distance D12 between one first capacitor structure CAP1 and one second capacitor structure CAP2, which are adjacent to each other in the second direction D2. It may be due to that the electrode connecting structure 120 is arranged between one the first capacitor structure CAP1 and one second capacitor structure CAP2, which are adjacent to each other in the second direction D2, so that the first capacitor structure CAP1 and the second capacitor structure CAP2 are separated.

According to some example embodiments, the plurality of first capacitor structures CAP1 and the plurality of second capacitor structures CAP2 may penetrate the mold structure MS within a dummy block DBLK. The plurality of first capacitor structures CAP1 and the plurality of second capacitor structures CAP2 may be separated from the channel structure CH in the third direction D3. The first block BLK1, where the plurality of first capacitor structures CAP1 and the plurality of second capacitor structures CAP2 are arranged, and the second block BLK2, where the channel structure CH is arranged, may be separated in the third direction D3 by the gate electrode cutting pattern WLC.

According to some example embodiments, the plurality of first capacitor structures CAP1 and the plurality of second capacitor structures CAP2 may be arranged in the same shape as the channel structure CH. For example, the plurality of first capacitor structures CAP1 and the plurality of second capacitor structures CAP2 may be arranged in a zigzag shape. The plurality of first capacitor structures CAP1 and the plurality of second capacitor structures CAP2 may be arranged alternately in the second direction D2 and the third direction D3. The plurality of first capacitor structures CAP1 and the plurality of second capacitor structures CAP2 may be arranged in a honeycomb shape.

According to some example embodiments, a width of the capacitor structure CAP and a width of the channel structure CH may be the same. For example, the width of the capacitor structure CAP may be or correspond to the diameter of or the longest axis of a capacitor hole CPH on the upper surface of the mold structure MS. For example, the width of the channel structure CH may be or correspond to the diameter of or the longest axis of the channel hole on the upper surface of the mold structure MS. In the string selection line SSL, which is placed at the top of the mold structure MS, the width WCAP of the capacitor structure may be the same as the width WCH of the channel structure. However, some example embodiments thereon are not limited thereto. The diameter of the capacitor hole CPH and the diameter of the channel hole may be different.

According to some example embodiments, the plurality of first capacitor structures CAP1 may be connected to a first capacitor connection structure 175a. The first capacitor connection structure 175a may be placed on the first block BLK1 on the first substrate 100a of the cell substrate. For example, the first capacitor connection structure 175a may be connected to the plurality of first capacitor structures CAP1. The first capacitor connection structure 175a may include a plurality of connecting lines extending in the third direction D3. Each of a plurality of connecting lines of the first capacitor connection structure 175a extending in the third direction D3 may be connected to the plurality of first capacitor structures CAP1 arranged in the third direction D3.

According to some example embodiments, the plurality of second capacitor structures CAP2 may be connected to a second capacitor connection structure 175b. The second capacitor connection structure 175b may be placed on the first block BLK1 on the first substrate 100a of the cell substrate. For example, the second capacitor connection structure 175b may be connected to all of the plurality of second capacitor structures CAP2. The second capacitor connection structure 175b may include a plurality of connecting lines extending in the third direction D3. Each of a plurality of connecting lines of the second capacitor connection structure 175b extending in the third direction D3 may be connected to the plurality of second capacitor structures CAP2 arranged in the third direction D3.

According to some example embodiments, the first capacitor connection structure 175a and the second capacitor connection structure 175b may be separated by the bit line BL in the third direction D3. The first capacitor connection structure 175a and the second capacitor connection structure 175b may be separated from the bit line BL with the gate electrode cutting pattern WLC interposed therebetween.

FIG. 3 and FIG. 4 illustrate that the first capacitor connection structure 175a connected to the plurality of first capacitor structures CAP1 arranged to be spaced apart in the second direction D2 with the plurality of second capacitor structures CAP2 in between (for example, the plurality of first capacitor structures CAP1 on the left and the plurality of first capacitor structures CAP1 on the right based on the plurality of second capacitor structures CAP2) are not connected to each other but are arranged to be separated in the second direction D2. However, example embodiments are not limited thereto. For example, it is apparent that the first capacitor connection structure 175a connected to the plurality of first capacitor structures CAP1 on the left based on the plurality of second capacitor structures CAP2 and the first capacitor connection structure 175a connected to the plurality of first capacitor structures CAP1 on the right side based on the plurality of second capacitor structures CAP2 may be connected through a separate connecting line extending in the second direction D2.

According to some example embodiments, the first capacitor connection structure 175a and the second capacitor connection structure 175b may be separated in the second direction D2. This may be due to the plurality of first capacitor structures CAP1 and the plurality of second capacitor structures CAP2 being separated in the second direction D2 with the electrode connecting structure 120 between them.

According to some example embodiments, the first capacitor structures CAP1 and the second capacitor structures CAP2 may receive different signals. The plurality of first capacitor structures CAP1 may receive a first signal V1, and the plurality of second capacitor structures CAP2 may receive a second signal V2. The level, e.g., the voltage level or the logic level, of the first signal V1 applied to the plurality of first capacitor structures CAP1 and the level, e.g., the voltage level or the logic level, of the second signal V2 applied to the plurality of second capacitor structures CAP2 may be different. The first signal V1 may be or may include or correspond to, for example, the power supply voltage. The second signal V2 may be or may include or correspond to, for example, ground voltage.

According to some example embodiments, each of the first signal V1 and the second signal V2 may be provided with the plurality of first capacitor structures CAP1 and the plurality of second capacitor structures CAP2 through the first capacitor connection structure 175a and the second capacitor connection structure 175b, respectively. Each of the first signal V1 and the second signal V2 may be provided to a peripheral circuit wiring structure 260 through an input/output pad 320 and the contact plug 166, and may be delivered to the first capacitor connection structure 175a and the second capacitor connection structure 175b.

According to some example embodiments, the first signal line connected to the first capacitor connection structure 175a and the second signal line connected to the second capacitor connection structure 175b may be electrically isolated. Each of the first signal line and the second signal line may be electrically isolated to provide different electrical signals to the first capacitor structures CAP1 and the second capacitor structures CAP2. The first signal line may provide the first signal V1 to the plurality of first capacitor structures CAP1 through the first capacitor connection structure 175a. The second signal line may provide the second signal V2 to the plurality of second capacitor structures CAP2 through the second capacitor connection structure 175b.

According to some example embodiments, each of the plurality of first capacitor structures CAP1 and the plurality of second capacitor structures CAP2 placed within one first block BLK1 is applied with the first signal V1 and the second signal V2 of different levels, and thus a capacitor formed by the plurality of first capacitor structures CAP1 and a capacitor formed by the plurality of second capacitor structures CAP2 may be connected in series with each other. For example, a capacitor formed by the wordline WL and a conductive film 172 of the first capacitor structure CAP1 and a capacitor formed by the wordline WL and the conductive film 172 of the second capacitor structure CAP2 may be connected in series.

Referring to FIG. 3, FIG. 4, FIG. 5 and FIG. 12, the plurality of first capacitor structures CAP1 may be electrically connected to the peripheral circuit wiring structure 260 of the peripheral circuit region PERI through the first capacitor connection structure 175a and a first cap bonding metal 177a. The plurality of first capacitor structures CAP1 may receive the first signal V1 from the peripheral circuit wiring structure 260 through the first capacitor connection structure 175a and the first cap bonding metal 177a.

According to some example embodiments, the plurality of second capacitor structures CAP2 may be electrically connected to the peripheral circuit wiring structure 260 of the peripheral circuit region PERI through the second capacitor connection structure 175b and a second cap bonding metal 177b. The plurality of second capacitor structures CAP2 may receive the second signal V2 from the peripheral circuit wiring structure 260 through the second capacitor connection structure 175b and the second cap bonding metal 177b.

According to some example embodiments, a capacitor connection structure 175 and a cap bonding metal 177 may be connected to the capacitor structure CAP. The capacitor connection structure 175 and the cap bonding metal 177 may be formed within a first inter-wire insulating film 145. The capacitor connection structure 175 may include the first capacitor connection structure 175a and the second capacitor connection structure 175b. The cap bonding metal 177 may include the first cap bonding metal 177a and the second cap bonding metal 177b.

FIG. 3, FIG. 4, FIG. 5 and FIG. 12 illustrate that the capacitor structure CAP does not receive signals directly from the input/output pad 320, but receives a signal through the peripheral circuit wiring structure 260. However, example embodiments are not limited thereto. The capacitor structure CAP is not connected to the peripheral circuit wiring structure 260 through the cap bonding metal 177, but may be directly connected to the input/output pad 320, such as the contact plug 166. For example, the capacitor structure CAP is electrically connected to the input/output pad 320 through contacts or wiring connected to the capacitor structure CAP on the second substrate 100b of the cell substrate, and may directly receive signals from the input/output pad 320.

Referring to FIG. 8, the capacitor structure CAP may be placed within the capacitor hole CPH. The capacitor hole CPH may penetrate the mold structure MS in the first direction D1. The capacitor structure CAP may include a dielectric film 171, the conductive film 172, and a filling film 173.

According to some example embodiments, the dielectric film 171 may extend along the capacitor hole CPH. The dielectric film 171 may come into contact with the mold structure MS within the capacitor hole CPH. FIG. 8 illustrates that the dielectric film 171 extends only along the inner wall of the capacitor hole CPH, but example embodiments are not limited thereto. For example, it is apparent that the dielectric film 171 may also be placed on the bottom surface of the capacitor hole CPH so as to be in contact with the cell substrate 100 within the capacitor hole CPH.

According to some example embodiments, the dielectric film 171 may include a high dielectric material including silicon oxide, silicon nitride, silicon oxynitride, and a metal. It is illustrated that the dielectric film 171 is a single film, but it is for convenience of explanation only, and the dielectric film 171 is not limited thereto.

According to some example embodiments, the dielectric film 171 may include a laminated film structure in which zirconium oxide, aluminum oxide, and zirconium oxide are sequentially laminated. The dielectric film 171 may include a dielectric film containing hafnium (Hf). The dielectric film 171 may have a laminated film structure of a ferroelectric material film and a paraelectric material film.

According to some example embodiments, the conductive film 172 may be placed on the dielectric film 171 within the capacitor hole CPH. The conductive film 172 may extend along the dielectric film 171. The conductive film 172 may include, for example, a doped semiconductor material, a conductive metal nitride (for example, titanium nitride, tantalum nitride, niobium nitride and/or tungsten nitride), a metal (for example, ruthenium, iridium, titanium and/or tantalum), and a conductive metal oxide (for example, iridium oxide and/or niobium oxide). However, the conductive film 172 is not limited thereto.

According to some example embodiments, the filling film 173 may be placed on the conductive film 172 within the capacitor hole CPH. The filling film 173 may fill the capacitor hole CPH on the conductive film 172. The filling film 173 may be surrounded by the conductive film 172. The filling film 173 may include an insulating material, for example, at least one of silicon oxide, silicon nitride and silicon oxynitride. However, the filling film 173 is not limited thereto.

According to some example embodiments, a capacitor may be formed by the conductive film 172, the dielectric film 171, and a plurality of gate electrodes (the ground selection line GSL, the wordline WL, and the string selection line SSL). For example, each of the first capacitor structure CAP1 and the second capacitor structure CAP2 may have an equivalent circuit in which a plurality of capacitors are connected in parallel, each of which is formed by the plurality of wordlines WL and the conductive film 172 and the dielectric film 171 therebetween.

Referring to FIG. 9, the capacitor structure CAP may contain or define a void (vo). The void (vo) may be surrounded by the conductive film 172 within the capacitor hole CPH. The void (vo) may contain air such as but not limited to clean, dry air.

Referring back to FIG. 3, FIG. 4 and FIG. 10, the electrode connecting structure 120 may penetrate the mold structure MS in the first direction D1 within the first block BLK1. The electrode connecting structure 120 may penetrate the mold structure MS and connect to the plurality of gate electrodes (the ground selection line GSL, the wordline WL, and the string selection line SSL). The electrode connecting structure 120 may connect the plurality of gate electrodes (the ground selection line GSL, the wordline WL, and the string selection line SSL).

According to some example embodiments, the electrode connecting structure 120 may be placed between the capacitor structure CAP in the second direction D2. For example, in the second direction D2, the electrode connecting structure 120 may be placed between the first capacitor structure CAP1 and the second capacitor structure CAP2. In the third direction, the electrode connecting structure 120 may be arranged in a zigzag shape. The electrode connecting structure 120 may include a conductive material, for example, a metal such as tungsten (W), cobalt (Co), nickel (Ni), or a semiconductor material such as silicon. However, the electrode connecting structure 120 is not limited thereto.

According to some example embodiments, plurality of gate electrodes (the ground selection line GSL, the wordline WL, and the string selection line SSL) connected by the electrode connecting structure 120 within the first block BLK1 may be electrically floating. For example, in the first block BLK1, voltage may not be applied to the electrode connecting structure 120 or the plurality of gate electrodes (the ground selection line GSL, the wordline WL, and the string selection line SSL).

Referring to FIG. 11, in the first block BLK1, the electrode connecting line (the electrode connecting structure 120 in FIG. 10) is not placed, and an insulation pillar 125 may be placed. The insulation pillar 125 may penetrate the mold structure MS in the first direction D1 within the first block BLK1. The insulation pillar 125 may penetrate the mold structure MS and come into contact with the plurality of gate electrodes (the ground selection line GSL, the wordline WL, and the string selection line SSL). The insulation pillar 125 may insulate a plurality of gate electrodes (the ground selection line GSL, the wordline WL, and the string selection line SSL) without electrically connecting them. The insulation pillar 125 may include an insulating material, for example, at least one of silicon oxide, silicon nitride and silicon oxynitride, but the insulation pillar 125 is not limited thereto.

According to some example embodiments, the insulation pillar 125 may be placed between the first capacitor structure CAP1 and the second capacitor structure CAP2 in the second direction D2. In order to prevent electrical short-circuiting due to the small gap between the first capacitor structure CAP1 and the second capacitor structure CAP2, which receive different signals, the insulation pillar 125 may be placed between the first capacitor structure CAP1 and the second capacitor structure CAP2.

Referring to FIG. 13, according to some example embodiments, the cell wiring structure 180 may be formed on the mold structure MS. For example, the first inter-wire insulating film 145 may be formed on the first interlayer insulating film 140, and the cell wiring structure 180 may be formed within the first inter-wire insulating film 145. The cell wiring structure 180 may be electrically connected to the bit line BL, the gate contact 162, a source contact 164, and the contact plug 166. Through this, the cell wiring structure 180 may be electrically connected to the channel structure CH, the gate electrode (the ground selection line GSL, the wordline WL, and the string selection line SSL) and the cell substrate 100. The illustrated number of floors and/or layout of the cell wiring structure 180 are not limited thereto.

According to some example embodiments, the cell wiring structure 180 may be electrically connected to a plurality of memory cells formed in the cell array region CAR. For example, the cell wiring structure 180 may be electrically connected to the bit line BL. Through this, the cell wiring structure 180 may be electrically connected to the channel structure CH. Further, the cell wiring structure 180 is electrically connected to the gate contact 162, thereby being electrically connected to the gate electrode (the ground selection line GSL, the wordline WL, and the string selection line SSL).

According to some example embodiments, the gate contact 162 may be connected to each gate electrode (the ground selection line GSL, the wordline WL, and the string selection line SSL). For example, the gate contact 162 extends in the first direction D1 within the first interlayer insulating film 140 and may be connected to each gate electrode (the ground selection line GSL, the wordline WL, and the string selection line SSL). In some example embodiments, the gate contact 162 may have a bend between the first mold structure and the second mold structure.

According to some example embodiments, the source contact 164 may be connected to the cell substrate 100. For example, the source contact 164 may extend in the first direction D1 within the first interlayer insulating film 140 and be connected to the cell substrate 100. The source contact 164 may electrically connect the cell substrate 100 and the cell wiring structure 180.

According to some example embodiments, the peripheral circuit region PERI may include a peripheral circuit substrate 200, a peripheral circuit device PT, and the peripheral circuit wiring structure 260.

According to some example embodiments, the peripheral circuit substrate 200 may be placed under the cell substrate 100. For example, the peripheral circuit substrate 200 may face the first substrate 100a of the cell substrate. The peripheral circuit substrate 200 may include a semiconductor substrate, such as, for example, a silicon substrate, a germanium substrate and a silicon-germanium substrate. Alternatively, the peripheral circuit substrate 200 may include a SOI substrate or a GOI substrate.

According to some example embodiments, the peripheral circuit device PT may be formed on the peripheral circuit substrate 200. The peripheral circuit device PT may constitute or correspond to a peripheral circuit (for example, the peripheral circuit 30 in FIG. 1) that controls the operation of a semiconductor memory device. For example, the peripheral circuit device PT may include control logic (for example, the control logic 37 of FIG. 1), a row decoder (for example, the row decoder 33 of FIG. 1), and a page buffer (for example, the page buffer 35 of FIG. 1). In the following description, the surface of the peripheral circuit substrate 200 on which the peripheral circuit device PT is placed may be referred to as a first substrate 200a of the peripheral circuit substrate. The first substrate 200a of the peripheral circuit substrate may be the front side of the peripheral circuit substrate 200. Conversely, the surface of the peripheral circuit substrate 200 opposite to the first substrate 200a of the peripheral circuit substrate may be referred to as a second substrate 200b of the peripheral circuit substrate. The second substrate 200b of the peripheral circuit substrate may be the back side of the peripheral circuit substrate.

According to some example embodiments, the peripheral circuit device PT may include, for example, a transistor, but the peripheral circuit device PT is not limited thereto. For example, the peripheral circuit device PT may include various active elements such as transistors, as well as various passive elements such as one or more of capacitors, resistors and inductors.

According to some example embodiments, the cell structure CELL may be stacked on the peripheral circuit structure PERI. For example, the cell structure CELL may be laminated on a second inter-wire insulating film 240.

A number of layers such as a number of metal layers, and/or an orientation of the layers and/or a thickness of each of the layers is not limited to features illustrated in the figures. Alternatively or additionally, in some example embodiments the peripheral circuit device PT may be or include a planar transistor and/or a three-dimensional transistor; example embodiments are not limited thereto.

According to some example embodiments, the first substrate 100a of the cell substrate may face the peripheral circuit structure PERI. For example, the first substrate 100a of the cell substrate may face the first substrate 200a of the peripheral circuit substrate.

According to some example embodiments, semiconductor memory devices may have a chip to chip (C2C) structure. In the C2C structure, an upper portion chip including the cell structure CELL is fabricated on a first wafer (for example, the cell substrate 100), a lower portion chip including the peripheral circuit structure PERI is fabricated on a second wafer (for example, the peripheral circuit substrate 200) different from the first wafer, and then the upper portion chip and the lower portion chip are connected to each other by a bonding method.

In some example embodiments, the bonding method may indicate a method of electrically connecting a first bonding metal 195 formed on an upper portion metal layer of the upper portion chip and a second bonding metal 295 formed on an upper portion metal layer of the lower portion chip. For example, when the first bonding metal 195 and the second bonding metal 295 are formed of copper (Cu), the bonding method may be or may include a Cu—Cu bonding method. However, it is a mere example embodiment, and it is apparent that the first bonding metal 195 and the second bonding metal 295 may alternatively or additionally be formed from a variety of other metals, such as one or more of aluminum (Al) and tungsten (W).

According to some example embodiments, as the first bonding metal 195 and the second bonding metal 295 are bonded, the cell wiring structure 180 may be connected to the peripheral circuit wiring structure 260. Through this, the bit line BL, each gate electrode (the ground selection line GSL, the wordline WL, and the string selection line SSL) and/or the cell substrate 100 may be electrically connected to the peripheral circuit device PT.

According to some example embodiments, the input/output pad 320 may be placed on the second substrate 100b of the cell substrate 100. For example, a second interlayer insulating film 310 covering the cell substrate 100 and the insulation substrate 101 may be formed on the second substrate 100b of the cell substrate 100. The input/output pad 320 may be formed on the second interlayer insulating film 310. The second interlayer insulating film 310 may include, for example, at least one of silicon oxide, silicon oxynitride, and a low-k material having a lower dielectric permittivity than silicon oxide. However, the second interlayer insulating film 310 is not limited thereto.

According to some example embodiments, the input/output pad 320 may be electrically connected to the cell structure CELL and/or the peripheral circuit structure PERI. For example, the contact plug 166 may be formed to connect the cell wiring structure 180 and the input/output pad 320. For example, the contact plug 166 may extend in the first direction D1 and penetrate the second interlayer insulating film 310, the insulation substrate 101 and the first interlayer insulating film 140. The input/output pad 320 may be electrically connected to the cell wiring structure 180 via the contact plug 166.

According to some example embodiments, the width of the contact plug 166 may decrease as it faces the cell wiring structure 180. This may be due to the characteristics of the etching process for forming the contact plug 166.

According to some example embodiments, an insulating spacer may be formed extending along the side of the contact plug 166. For example, the insulating spacer may surround the side of the contact plug 166. For example, the insulating spacer may include, for example, at least one of silicon oxide, silicon nitride and silicon oxynitride. However, the insulating spacer is not limited thereto.

According to some example embodiments, a capping insulation film 330 may be formed on the input/output pad 320. The capping insulation film 330 may include a pad opening OP that exposes at least a portion of the input/output pad 320. The input/output pad 320 may be electrically connected to external devices through the pad opening OP.

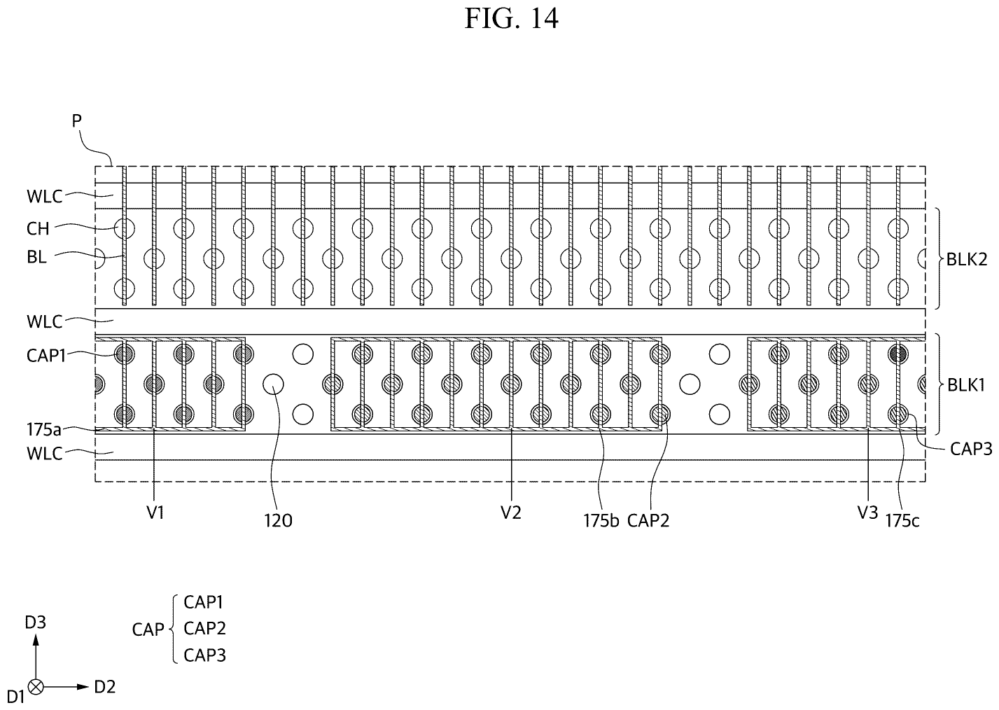

FIG. 14 is a drawing illustrating an enlarged portion P of FIG. 3 according to some example embodiments in order to describe a semiconductor memory device according to some other example embodiments. In order to help understanding the semiconductor memory device according to some other example embodiments, the following explains the differences from the descriptions with reference to FIG. 1 to FIG. 13.

Referring to FIG. 14, in the first block BLK1, the capacitor structure CAP may include the first capacitor structure CAP1, the second capacitor structure CAP2 and a third capacitor structure CAP3. Each of the first capacitor structure CAP1, the second capacitor structure CAP2 and the third capacitor structure CAP3 may be connected to the first capacitor connection structure 175a, the second capacitor connection structure 175b, and a third capacitor connection structure 175c. Through the first capacitor connection structure 175a, the second capacitor connection structure 175b and the third capacitor connection structure 175c, the first signal V1, the second signal V2 and a third signal V3 may be applied to the first capacitor structure CAP1, the second capacitor structure CAP2 and the third capacitor structure CAP3, respectively. The signal levels of the first signal V1, the second signal V2 and the third signal V3 may all be different.

According to some example embodiments, as the first signal V1 is applied to the first capacitor structure CAP1, a first capacitor may be formed by a plurality of gate electrodes (the ground selection line GSL, the wordline WL, and the string selection line SSL of FIG. 12) and a conductive film (the conductive film 172 of FIG. 8 and FIG. 9) and a dielectric film (the dielectric film 171 of FIG. 8 and FIG. 9) of the first capacitor structure CAP1. As the second signal V2 is applied to the second capacitor structure CAP2, a second capacitor may be formed by a plurality of gate electrodes e.g., (the ground selection line GSL, the wordline WL, and the string selection line SSL of FIG. 12) and a conductive film (the conductive film 172 of FIG. 8 and FIG. 9) and a dielectric film (the dielectric film 171 of FIG. 8 and FIG. 9) of the second capacitor structure CAP2. As the third signal V3 is applied to the third capacitor structure CAP3, a third capacitor may be formed by a plurality of gate electrodes (the ground selection line GSL, the wordline WL, and the string selection line SSL of FIG. 12) and a conductive film (the conductive film 172 of FIG. 8 and FIG. 9) and a dielectric film (the dielectric film 171 of FIG. 8 and FIG. 9) of the third capacitor structure CAP3. The first capacitor, the second capacitor, and the third capacitor may be connected in series.

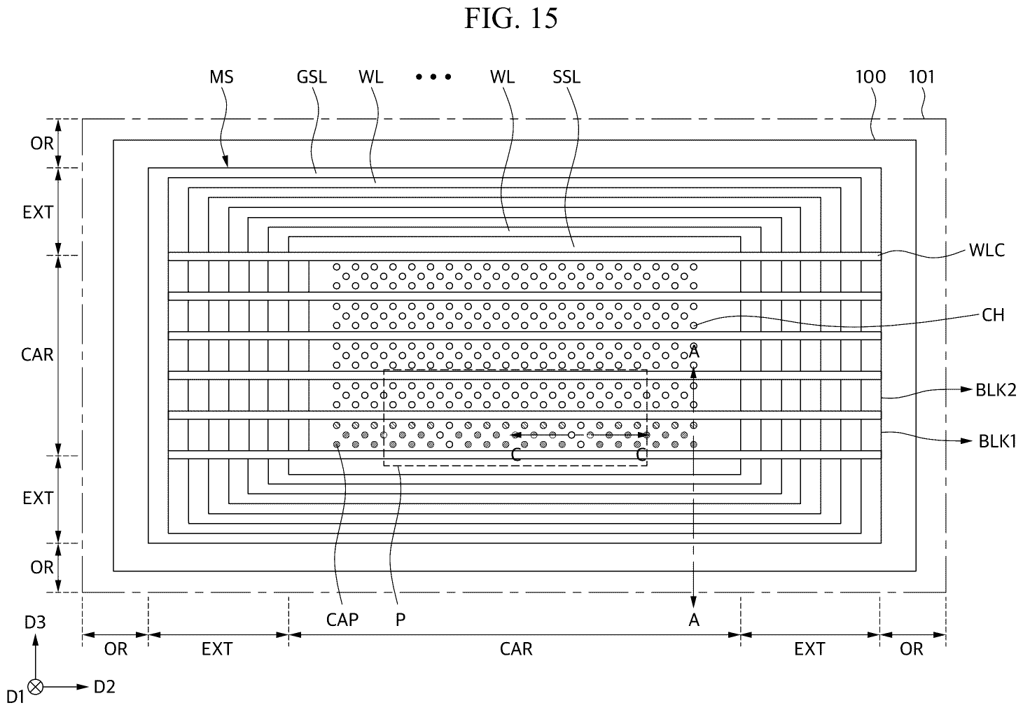

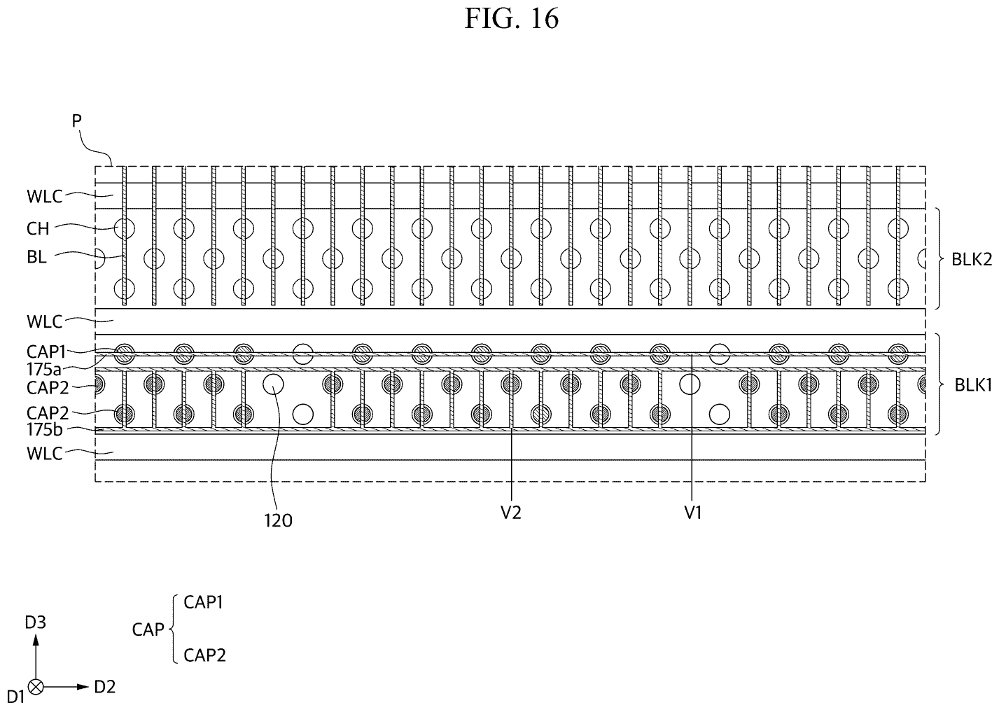

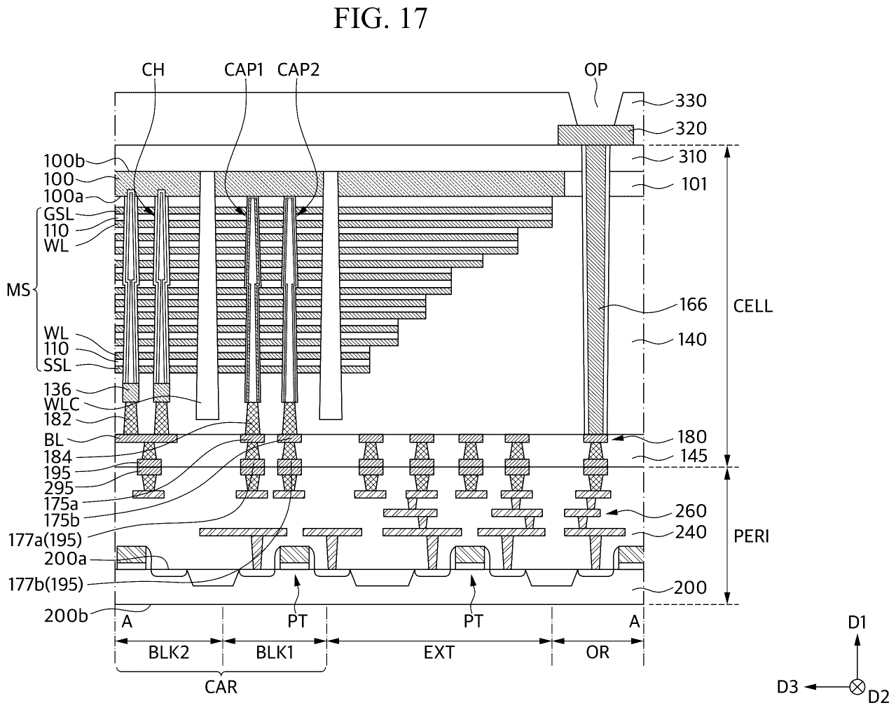

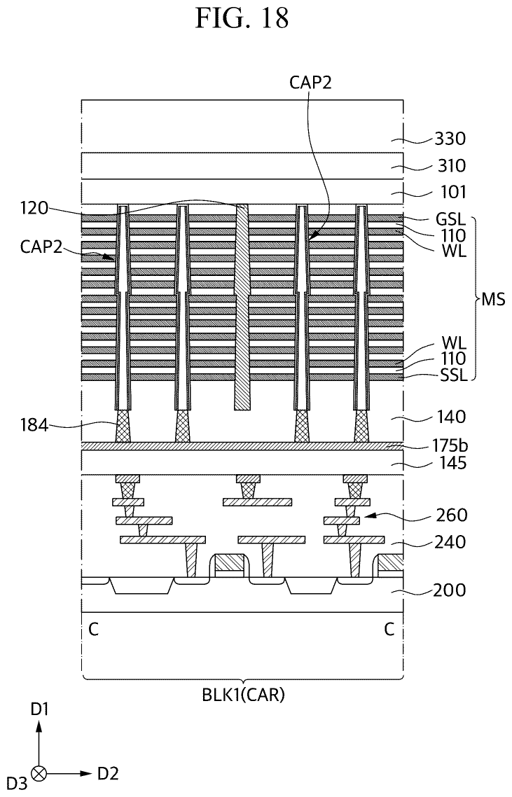

FIG. 15 is a schematic layout drawing in order to describe a semiconductor memory device according to another example embodiment. FIG. 16 is a drawing illustrating an enlarged portion P of FIG. 15 according to some example embodiments. FIG. 17 is a drawing illustrating a cross-section taken along line A-A of FIG. 15 according to some example embodiments. FIG. 18 is a drawing illustrating a cross-section taken along line C-C of FIG. 15 according to some example embodiments. In order to help understanding the semiconductor memory device according to some other example embodiments, the following explains the differences from the descriptions with reference to FIG. 1 to FIG. 13.

Referring to FIG. 15 to FIG. 18, the plurality of first capacitor structures CAP1 may be arranged along the second direction D2. The plurality of second capacitor structures CAP2 may be arranged along the second direction D2. The plurality of first capacitor structures CAP1 and the plurality of second capacitor structures CAP2 may be spaced apart in the third direction D3.

According to some example embodiments, the first capacitor connection structure 175a connecting the plurality of first capacitor structures CAP1 and the second capacitor connection structure 175b connecting the plurality of second capacitor structures CAP2 may be spaced apart from each other in the third direction D3. The first capacitor connection structure 175a and the second capacitor connection structure 175b may be spaced apart from the bit line BL of the second block BLK2 in the third direction D3. The first capacitor connection structure 175a and the second capacitor connection structure 175b may be arranged at the same height level as the bit line BL along the first direction D1. The bit line BL, the first capacitor connection structure 175a and the second capacitor connection structure 175b may be arranged on the first substrate 100a of the cell substrate.

According to some example embodiments, the first signal V1 may be applied to the plurality of first capacitor structures CAP1 through the first capacitor connection structure 175a, and the second signal V2 may be applied to the plurality of second capacitor structures CAP2 through the second capacitor connection structure 175b. The first capacitor formed by the plurality of first capacitor structures CAP1 by the first signal V1 being applied thereto and the second capacitor formed by the plurality of second capacitor structures CAP2 by the second signal V2 being applied thereto may be connected in series with each other.

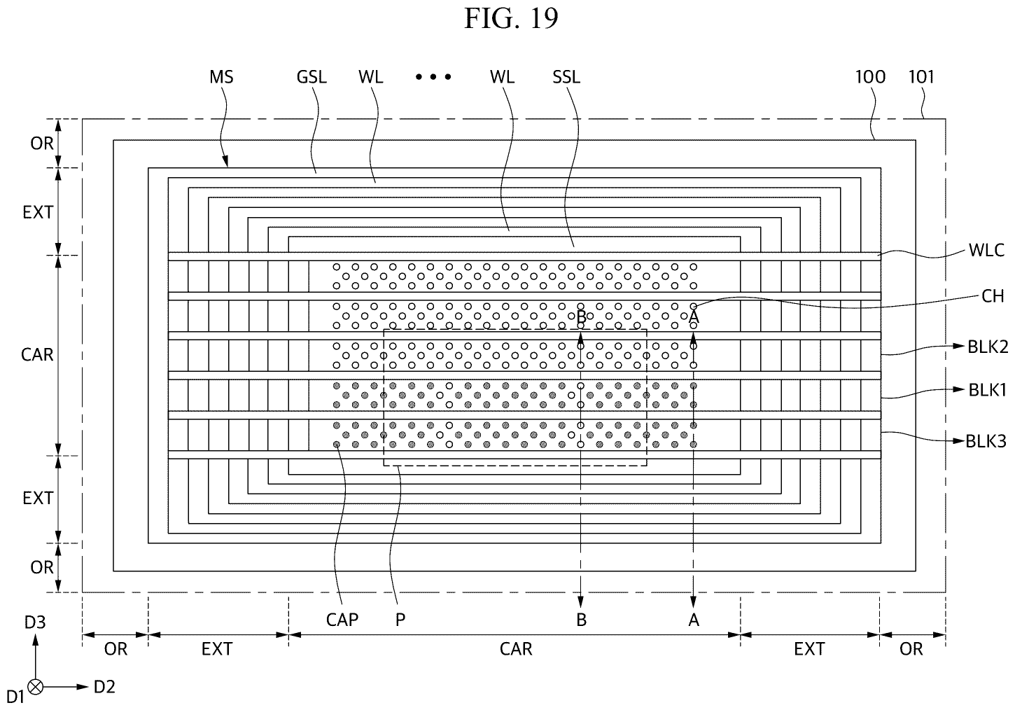

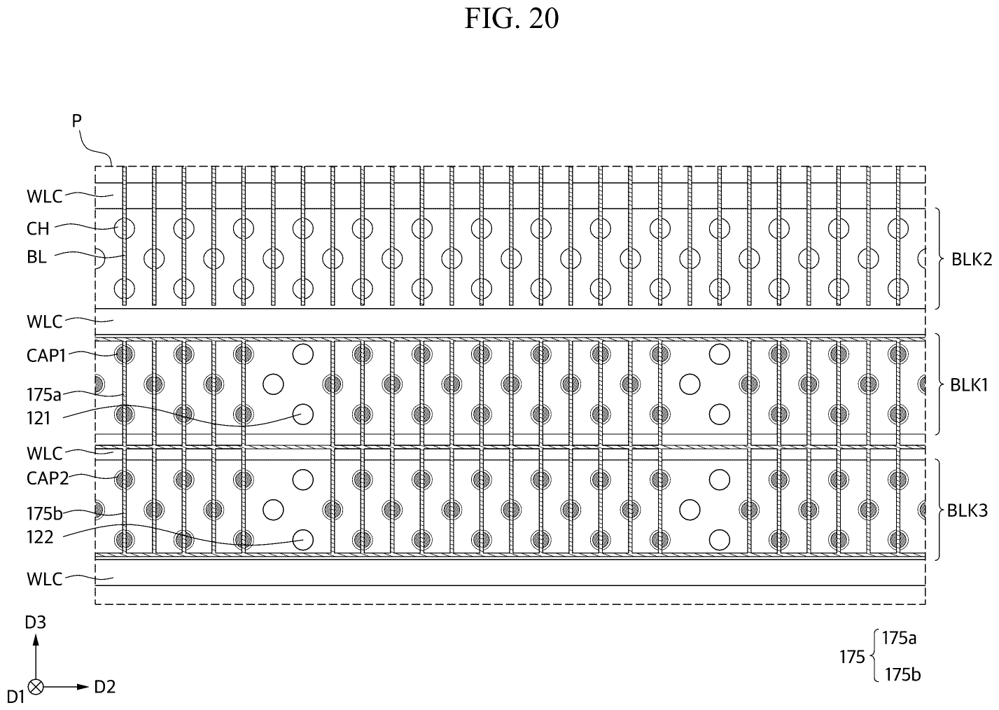

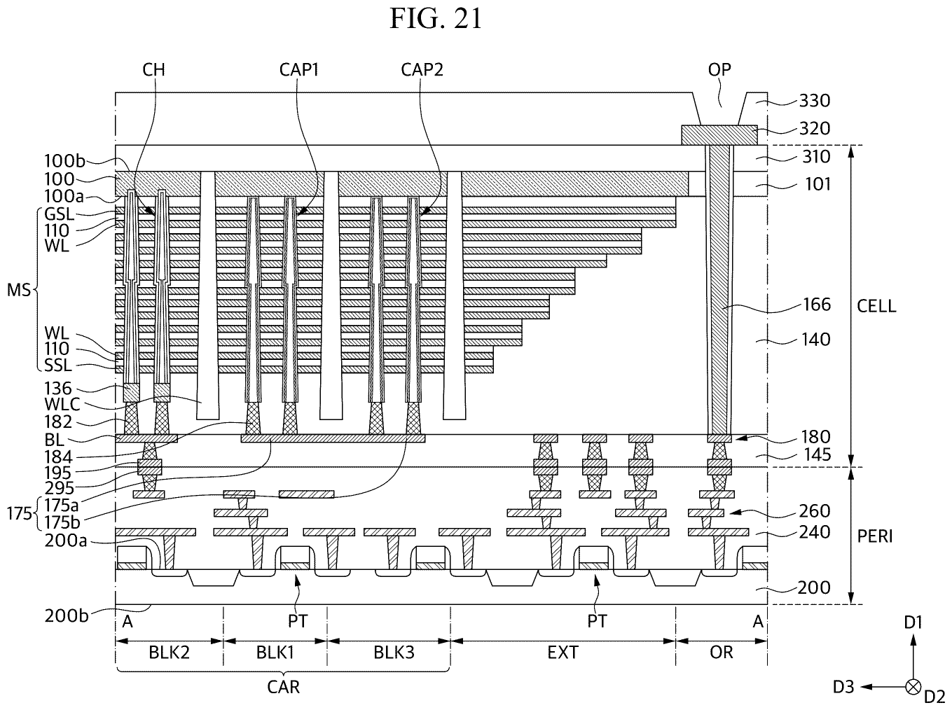

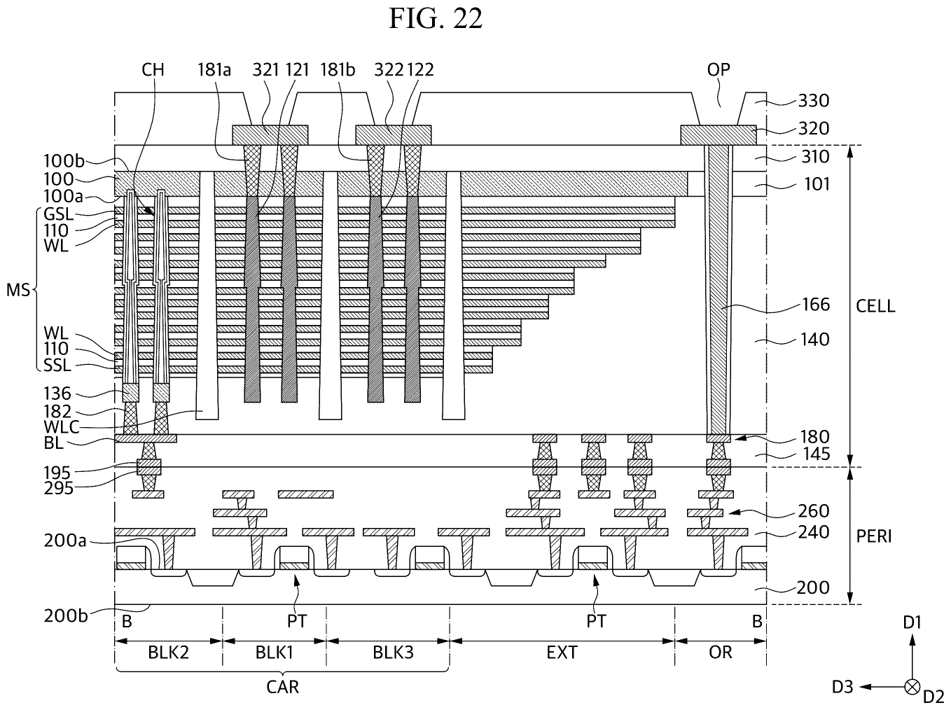

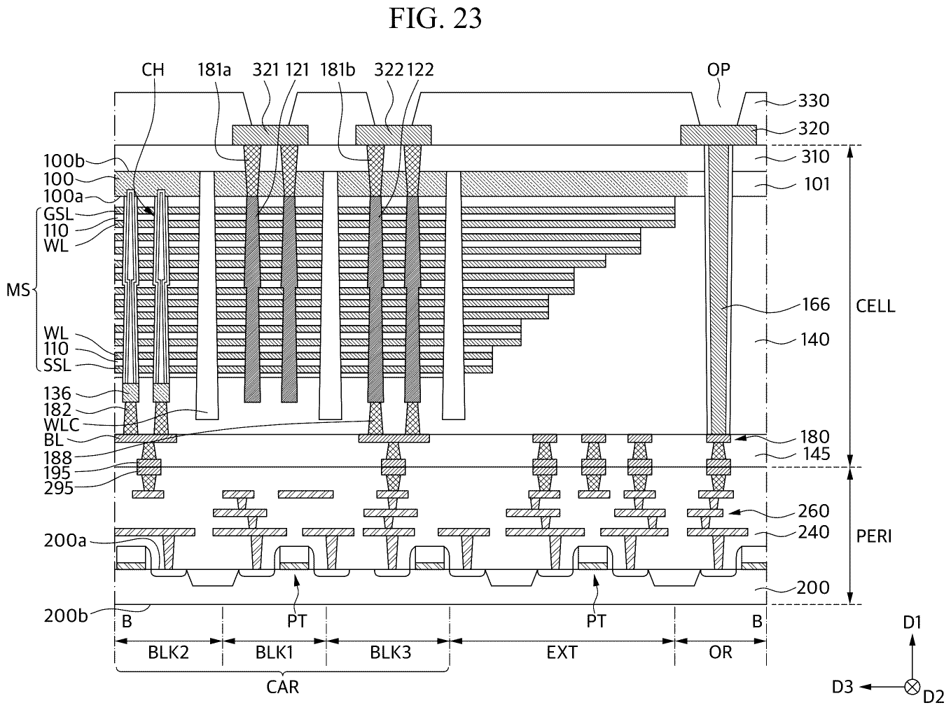

FIG. 19 is a schematic layout drawing to describe a semiconductor memory device according to some example embodiments. FIG. 20 is a drawing illustrating an enlarged portion P of FIG. 19 according to some example embodiments. FIG. 21 is a drawing illustrating a cross-section taken along line A-A of FIG. 19 according to some example embodiments. FIG. 22 is a drawing illustrating a cross-section taken along line B-B of FIG. 19 according to some example embodiments. FIG. 23 is another drawing illustrating a cross-section taken along line B-B of FIG. 19 according to some example embodiments. In order to help understanding the semiconductor memory device according to some example embodiments, the following explains the differences from the description with reference to FIG. 1 to FIG. 18.

Referring to FIG. 19 to FIG. 23, the mold structure MS may include the first block BLK1, the second block BLK2 and a third block BLK3. The first block BLK1, the second block BLK2 and the third block BLK3 may be arranged in the third direction D3. In the third direction D3, the third block BLK3 may be placed outside the first block BLK1 and the second block BLK2. In the third direction D3, the first block BLK1 may be placed between the second block BLK2 and the third block BLK3.

According to some example embodiments, the plurality of first capacitor structures CAP1 may be placed within the first block BLK1. The plurality of first capacitor structures CAP1 may penetrate the mold structure MS within the first block BLK1. The plurality of first capacitor structures CAP1 may be connected to the first capacitor connection structure 175a. Based on the first substrate 100a of the cell substrate, the first capacitor connection structure 175a may be placed on the first block BLK1.

According to some example embodiments, the plurality of second capacitor structures CAP2 may be placed within the third block BLK3. The plurality of second capacitor structures CAP2 may penetrate the mold structure MS within the third block BLK3. The plurality of second capacitor structures CAP2 may be connected to the second capacitor connection structure 175b. Based on the first substrate 100a of the cell substrate, the second capacitor connection structure 175b may be placed on the third block BLK3.

According to some example embodiments, the first capacitor connection structure 175a and the second capacitor connection structure 175b may be connected. For example, the first capacitor connection structure 175a and the second capacitor connection structure 175b may overlap with the gate electrode cutting pattern WLC between the first block BLK1 and the third block BLK3, and may be connected to each other through a line extending in the second direction D2. Since the first capacitor connection structure 175a and the second capacitor connection structure 175b are connected to each other, the plurality of first capacitor structures CAP1 and the plurality of second capacitor structures CAP2 may be connected to each other. For example, when a specific signal is applied to the first capacitor connection structure 175a, the same signal may also be applied to the second capacitor connection structure 175b, the plurality of first capacitor structures CAP1, and the plurality of second capacitor structures CAP2.

According to some example embodiments, the first capacitor connection structure 175a and the second capacitor connection structure 175b may be electrically floating. Electrical signals may not be applied to the first capacitor connection structure 175a and the second capacitor connection structure 175b.

According to some example embodiments, a first electrode connecting structure 121 may be placed within the first block BLK1. The first electrode connecting structure 121 may penetrate the mold structure MS within the first block BLK1. The first electrode connecting structure 121 may connect the plurality of gate electrodes (the ground selection line GSL, the wordline WL, and the string selection line SSL) of the first block BLK1.

According to some example embodiments, the first electrode connecting structure 121 may be connected to a first electrode connection wiring 321. The first electrode connecting structure 121 may be connected to the first electrode connection wiring 321 through a first via 181a. The first signal may be applied through the first electrode connection wiring 321. Therefore, through the first electrode connection wiring 321 and the first electrode connecting structure 121, the first signal may be applied to the plurality of gate electrodes (the ground selection line GSL, the wordline WL, and the string selection line SSL) within the first block BLK1.

According to some example embodiments, a second electrode connecting structure 122 may be placed within the third block BLK3. The second electrode connecting structure 122 may penetrate the mold structure MS within the third block BLK3. The second electrode connecting structure 122 may connect the plurality of gate electrodes (the ground selection line GSL, the wordline WL, and the string selection line SSL) of the third block BLK3.

According to some example embodiments, the second electrode connecting structure 122 may be connected to a second electrode connection wiring 322. The second electrode connecting structure 122 may be connected to the second electrode connection wiring 322 through a second via 181b. The second signal may be applied through the second electrode connection wiring 322. Therefore, through the second electrode connection wiring 322 and the second electrode connecting structure 122, a second signal may be applied to the plurality of gate electrodes (the ground selection line GSL, the wordline WL, and the string selection line SSL) within the third block BLK3.

According to some example embodiments, the first signal applied through the first electrode connection wiring 321 and the second signal applied through the second electrode connection wiring 322 may have different levels. For example, the first signal may be the power supply voltage and the second signal may be the ground voltage.

According to some example embodiments, the first electrode connection wiring 321 and the second electrode connection wiring 322 may be exposed to the outside through the opening from the capping insulation film 330. Through the first electrode connection wiring 321 and the second electrode connection wiring 322, the signal may be directly applied to the plurality of gate electrodes (the ground selection line GSL, the wordline WL, and the string selection line SSL) of the first block BLK1 and the third block BLK3.

According to some example embodiments, in the first direction D1, the first electrode connection wiring 321 and the second electrode connection wiring 322 may be placed on the same side with respect to the mold structure MS. The first electrode connection wiring 321 and the second electrode connection wiring 322 may be arranged on the second substrate 100b of the cell substrate. In the first direction D1, the first electrode connection wiring 321 and the second electrode connection wiring 322 may be arranged on the opposite side of the capacitor connection structure 175 with respect to the mold structure MS. The capacitor connection structure 175 is placed on the first substrate 100a of the cell substrate, and the first electrode connection wiring 321 and the second electrode connection wiring 322 are arranged on the second substrate 100b of the cell substrate, and thus the capacitor connection structure 175, and the first electrode connection wiring 321 and the second electrode connection wiring 322 may be arranged on the opposite sides with respect to the mold structure MS in the first direction D1.

According to some example embodiments, as the first signal is applied through the first electrode connection wiring 321, a first capacitor may be formed by the plurality of gate electrodes (the ground selection line GSL, the wordline WL, and the string selection line SSL) and the conductive film of the first capacitor structure CAP1 (the conductive film 172 of FIG. 8 and FIG. 9) within the first block BLK1. As the second signal is applied to the second electrode connection wiring 322, a second capacitor may be formed within the third block BLK3 by the plurality of gate electrodes (the ground selection line GSL, the wordline WL, and the string selection line SSL) and the conductive film of the second capacitor structure CAP2 (the conductive film 172 of FIG. 8 and FIG. 9). The first capacitor structure CAP1 and the second capacitor structure CAP2 are connected through the first capacitor connection structure 175a and the second capacitor connection structure 175b, and thus the first capacitor formed in the first block BLK1 and the second capacitor formed in the third block BLK3 may be connected in series.

Referring to FIG. 22, the second electrode connecting structure 122 may not be connected to the cell wiring structure 180. The second electrode connecting structure 122 may not receive signals from the cell wiring structure 180, but may receive signals through the second electrode connection wiring 322.

Referring to FIG. 23, the second electrode connecting structure 122 may be connected to the cell wiring structure 180. For example, the second electrode connecting structure 122 may be electrically connected to the cell wiring structure 180 through a cell contact via 188. In addition to receiving a signal through the second electrode connection wiring 322, the second electrode connecting structure 122 may also receive a signal provided to the peripheral circuit wiring structure 260 through the input/output pad 320 and the contact plug 166 through the cell wiring structure 180.

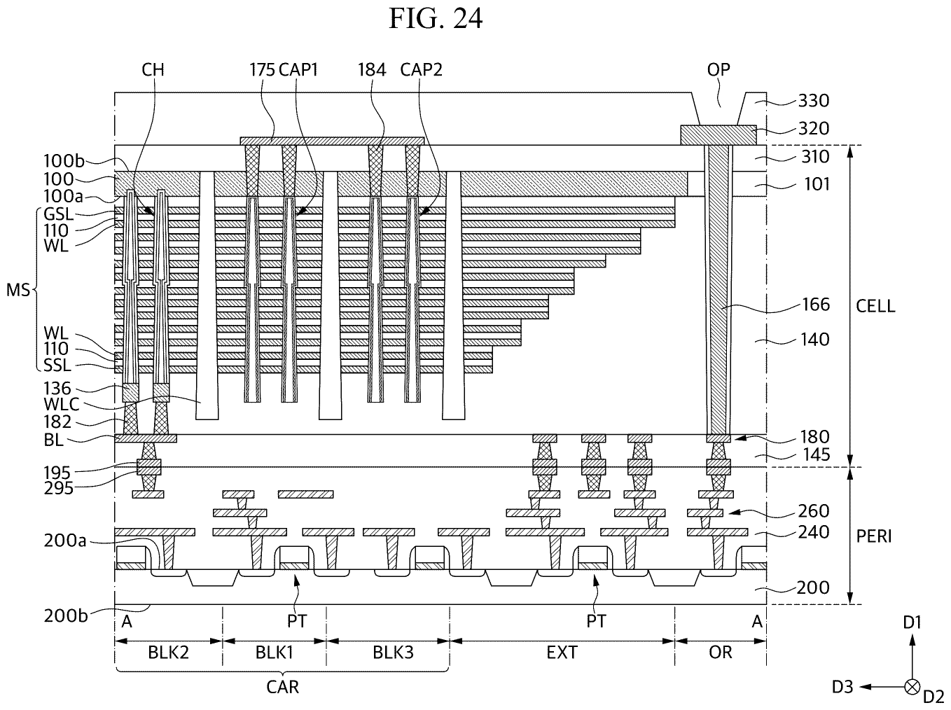

FIG. 24 is another drawing illustrating a cross-section taken along line A-A of FIG. 19 according to some example embodiments. In order to help understanding the semiconductor memory device according to some other example embodiments, the following description focuses on differences from the description with reference to FIG. 19 to FIG. 23.

Referring to FIG. 24, the capacitor connection structure 175 may be placed on the second substrate 100b of the cell substrate. The first capacitor connection structure 175a and the second capacitor connection structure 175b may be arranged on the second substrate 100b of the cell substrate. The first capacitor connection structure 175a may be connected to the plurality of first capacitor structures CAP1 on the second substrate 100b of the cell substrate. The second capacitor connection structure 175b may be connected to the plurality of second capacitor structures CAP2 on the second substrate 100b of the cell substrate.

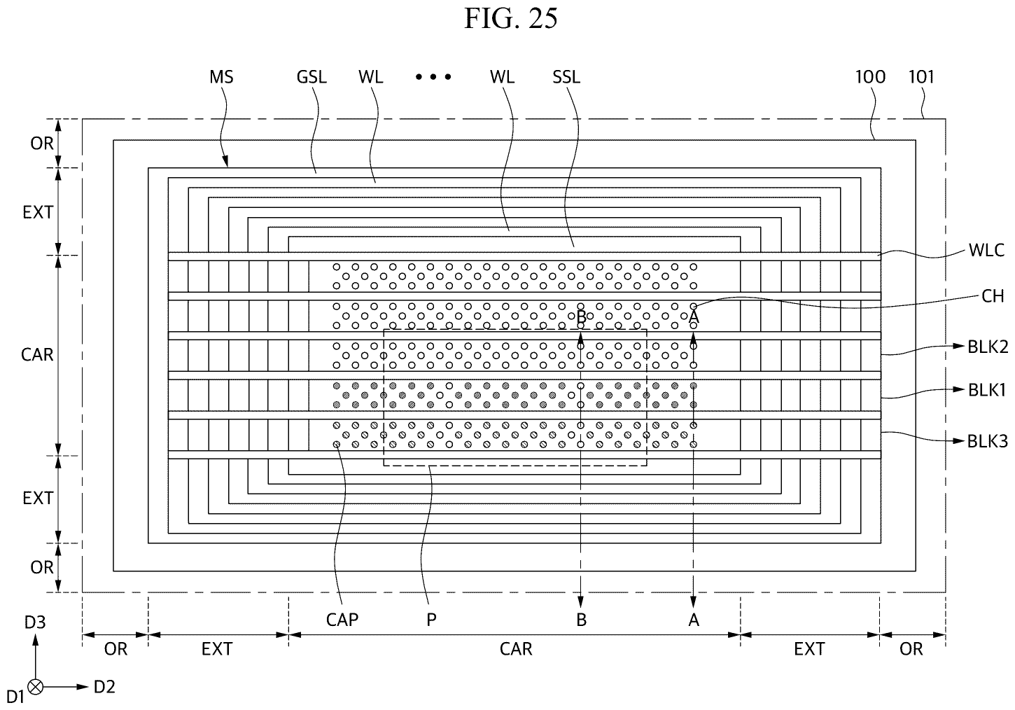

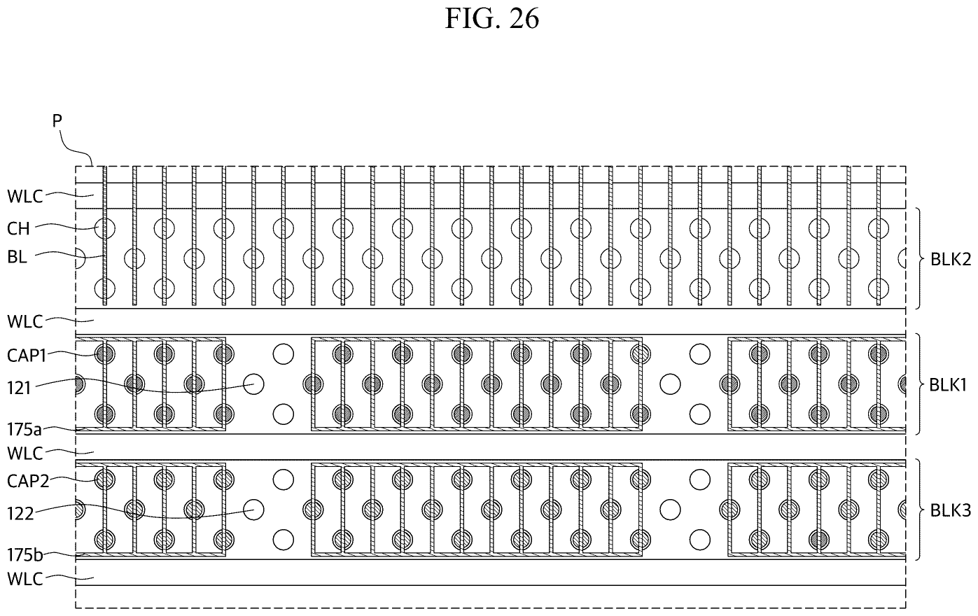

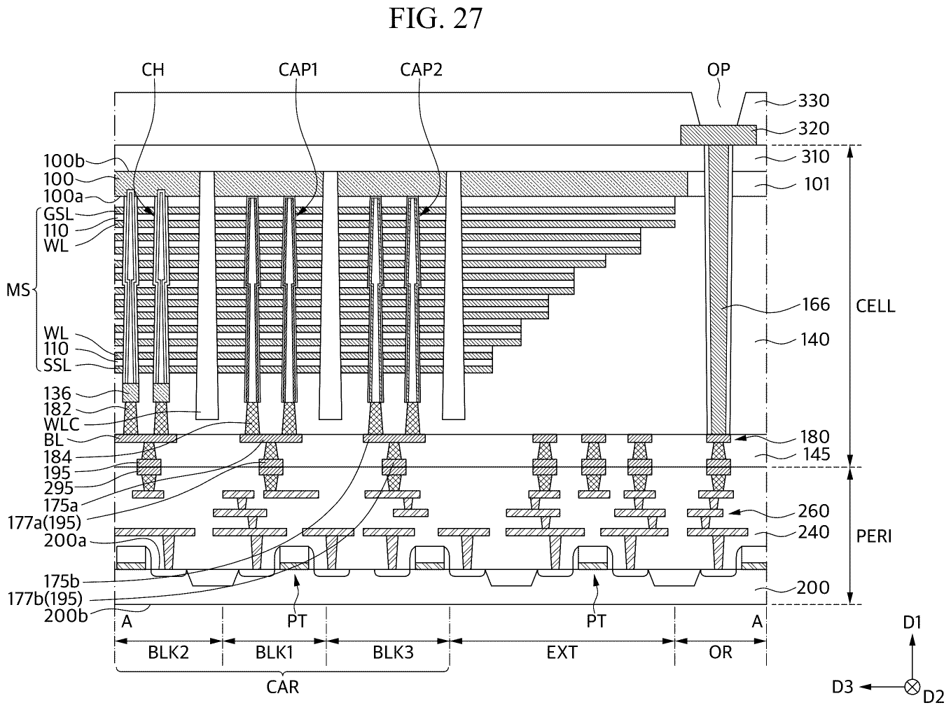

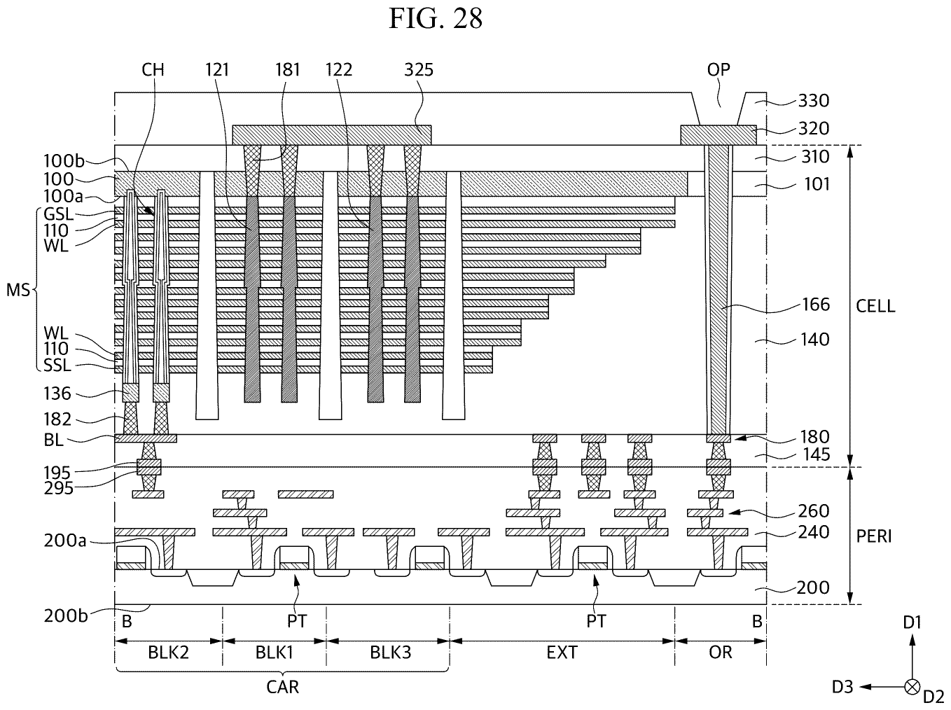

FIG. 25 is a schematic layout diagram illustrating a semiconductor memory device according to some example embodiments. FIG. 26 is a drawing illustrating an enlarged portion P of FIG. 25 according to some example embodiments. FIG. 27 is a drawing illustrating a cross-section taken along line A-A of FIG. 25 according to some example embodiments. FIG. 28 is a drawing illustrating a cross-section taken along line B-B of FIG. 25 according to some example embodiments. In order to help understanding the semiconductor memory device according to some other example embodiments, the following description focuses on differences from the description with reference to FIG. 19 to FIG. 23.

Referring to FIG. 25 to FIG. 28, the first capacitor connection structure 175a and the second capacitor connection structure 175b may be separated in the third direction D3 with the gate electrode cutting pattern WLC between them.

According to some example embodiments, the first capacitor connection structure 175a may be electrically connected to the peripheral circuit wiring structure 260 of the peripheral circuit region PERI through the first cap bonding metal 177a. Through the first capacitor connection structure 175a and the peripheral circuit wiring structure 260, the plurality of first capacitor structures CAP1 may receive the first signal applied to the input/output pad 320.

According to some example embodiments, the second capacitor connection structure 175b may be electrically connected to the peripheral circuit wiring structure 260 of the peripheral circuit region PERI through the second cap bonding metal 177b. Through the second capacitor connection structure 175b and the peripheral circuit wiring structure 260, the plurality of second capacitor structures CAP2 may receive a second signal applied to the input/output pad 320.

According to some example embodiments, the first electrode connecting structure 121 and the second electrode connecting structure 122 may be connected. A bridge connection wiring 325 extending in the third direction D3 may be arranged to overlap with the first block BLK1 and the third block BLK3. The bridge connection wiring 325 may be connected to the first electrode connecting structure 121 and the second electrode connecting structure 122. The bridge connection wiring 325 may be connected to the first electrode connecting structure 121 and the second electrode connecting structure 122 through a contact via 181.

According to some example embodiments, the first electrode connecting structure 121 and the second electrode connecting structure 122 may be electrically floated. An electrical signal may not be applied to the first electrode connecting structure 121 and the second electrode connecting structure 122.

According to some example embodiments, as the first signal is applied to the first capacitor connection structure 175a and the plurality of first capacitor structures CAP1, a first capacitor may be formed by the plurality of gate electrodes (the ground selection line GSL, the wordline WL, and the string selection line SSL) and the conductive film of the first capacitor structure CAP1 (the conductive film 172 of FIG. 8 and FIG. 9) within the first block BLK1. As the second signal is applied to the second capacitor connection structure 175b and the plurality of second capacitor structures CAP2, a second capacitor may be formed within the third block BLK3 by the plurality of gate electrodes (the ground selection line GSL, the wordline WL, and the string selection line SSL) and the conductive film of the second capacitor structure CAP2 (the conductive film 172 of FIG. 8 and FIG. 9). Since the first electrode connecting structure 121 and the second electrode connecting structure 122 are connected through the bridge connection wiring 325, the first capacitor formed in the first block BLK1 and the second capacitor formed in the third block BLK3 may be connected in series.

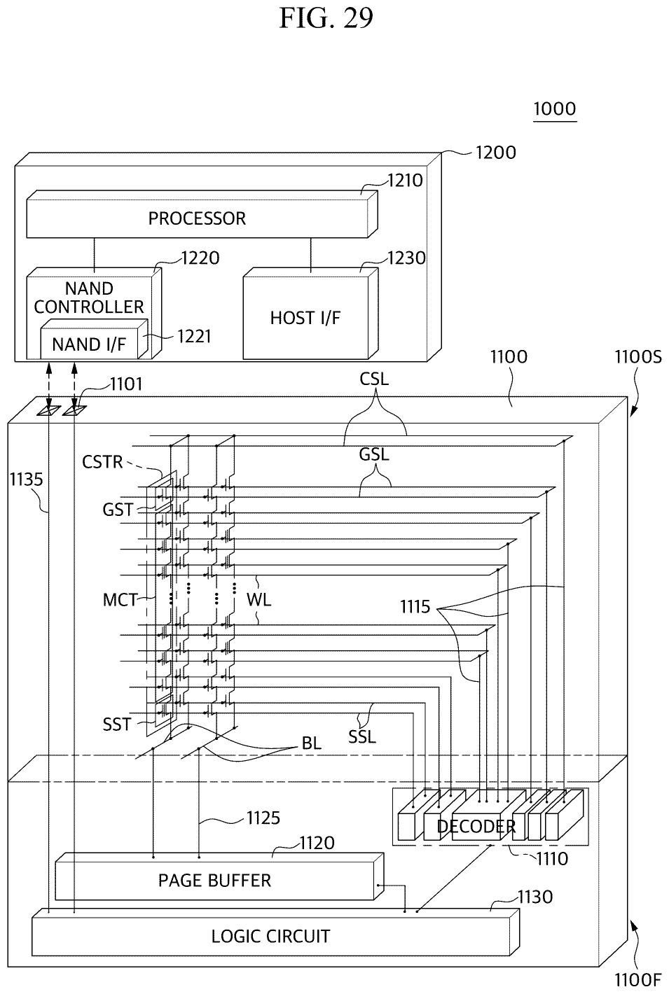

FIG. 29 is a drawing illustrating an electronic system including a semiconductor memory device according to some example embodiments.

Referring to FIG. 29, an electronic system 1000 may include a semiconductor memory device 1100 and a controller 1200 electrically connected to the semiconductor memory device 1100. The electronic system 1000 may be a storage device including one or more semiconductor memory devices 1100 or an electronic device including a storage device. For example, the electronic system 1000 may be a solid state drive device (SSD device), a universal serial bus (USB), a computing system, a medical device, or a communications device including one or more semiconductor memory devices 1100.

According to some example embodiments, the semiconductor memory device 1100 may be or may include or be included in a non-volatile memory device (for example, a NAND flash memory device). For example, the semiconductor memory device 1100 may be, include, or be included in a semiconductor memory device as described with reference to FIG. 1 to FIG. 28. The semiconductor memory device 1100 may include a first structure 1100F and a second structure 1100S on the first structure 1100F.

According to some example embodiments, the first structure 1100F may be a peripheral circuit structure including a decoder circuit (a decoder circuit 1110; for example, the row decoder 33 of FIG. 1), a page buffer (a page buffer 1120; for example, the page buffer 35 of FIG. 1), and a logic circuit (a logic circuit 1130; for example, the control logic 37 of FIG. 1). The first structure 1100F may correspond to the peripheral circuit structure PERI described using, for example, FIG. 1 to FIG. 28.

According to some example embodiments, the second structure 1100S may include the common source line CSL, a plurality of bit lines BL and the plurality of cell strings CSTR, as described with reference to FIG. 2. The cell strings CSTR may be connected to the decoder circuit 1110 through the wordline WL, at least one string selection line SSL, and at least one ground selection line GSL. Further, the cell strings CSTR may be connected to the page buffer 1120 through the bit lines BL. For example, the second structure 1100S may correspond to the cell structure CELL described with reference to FIG. 1 to FIG. 28.

According to some example embodiments, through a first connection wirings 1115 extending from the first structure 1100F to the second structure 1100S, the common source line CSL and the cell strings CSTR may be electrically connected to the decoder circuit 1110. Through second connection wirings 1125 extending from the first structure 1100F to the second structure 1100S, the bit lines BL may be electrically connected to the page buffer 1120.

According to some example embodiments, through an input/output pad 1101, which is electrically connected to the logic circuit (the logic circuit 1130; for example, the control logic 37 in FIG. 1), the semiconductor memory device 1100 may communicate with the controller 1200. Through an input/output connection wiring 1135 extending from the first structure 1100F to the second structure 1100S, the input/output pad 1101 may be electrically connected to the logic circuit 1130. The input/output connection wiring 1135 may correspond to the contact plug 166 described above using, for example, FIG. 1 to FIG. 28.

According to some example embodiments, the controller 1200 may include a processor 1210, a NAND controller 1220, and a host interface 1230. In some example embodiments, the electronic system 1000 may include a plurality of semiconductor memory devices 1100. In this case, the controller 1200 may control the plurality of semiconductor memory devices 1100.

According to some example embodiments, the processor 1210 may control the operation of the entire electronic system 1000, including the controller 1200. The processor 1210 may operate with certain firmware, and control the NAND controller 1220 to access the semiconductor memory device 1100. The NAND controller 1220 may include a NAND interface 1221 that handles communication with the semiconductor memory device 1100. Through the NAND interface 1221, control commands for controlling the semiconductor memory device 1100, data to be written to the memory cell transistors MCT of the semiconductor memory device 1100, data to be read from the memory cell transistors MCT of the semiconductor memory device 1100 may be transmitted. The host interface 1230 may provide communication between the electronic system 1000 and an external host. When receiving a control command from an external host through the host interface 1230, the processor 1210 may control the semiconductor memory device 1100 in response to the control command.

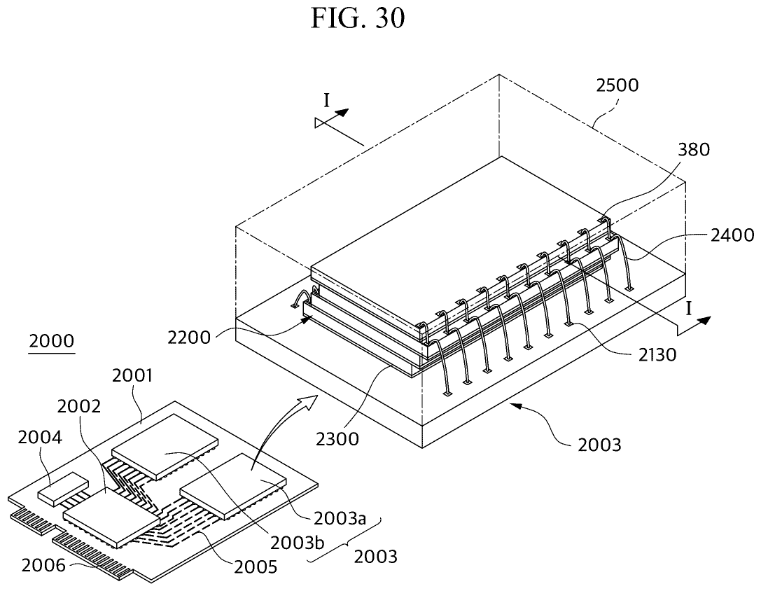

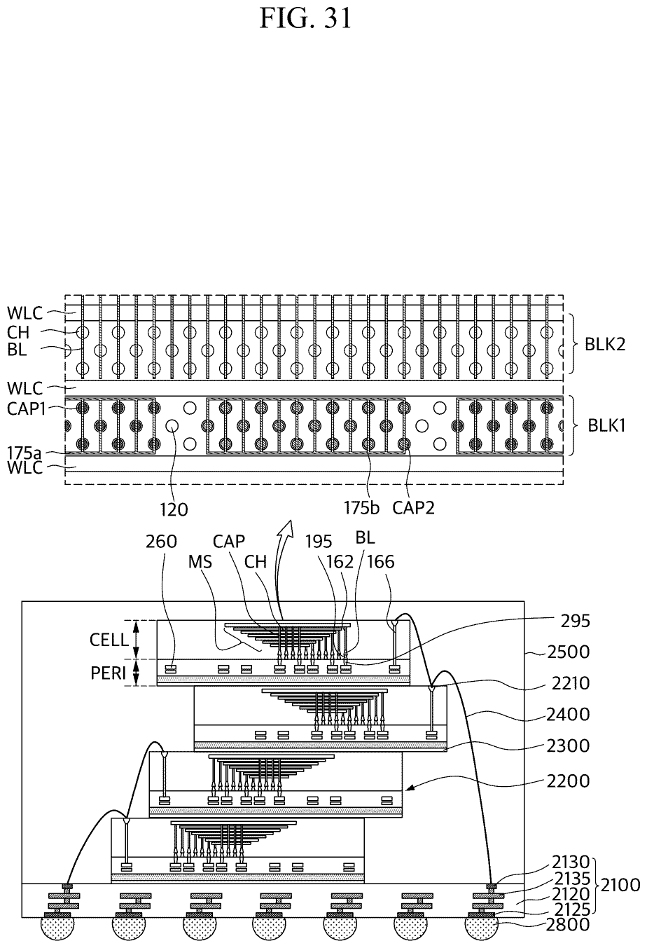

FIG. 30 is a perspective view to describe an electronic system including a semiconductor memory device according to some example embodiments. FIG. 31 is a drawing illustrating a cross-section taken along line I-I of FIG. 30 according to some example embodiments.

Referring to FIG. 30 and FIG. 31, an electronic system may include a main substrate 2001, a main controller 2002 mounted on the main substrate 2001, one or more semiconductor packages 2003, and a DRAM 2004. The semiconductor package 2003 and the DRAM 2004 may be interconnected with the main controller 2002 by wiring patterns 2005 formed on the main substrate 2001.

According to some example embodiments, the main substrate 2001 may include a connector 2006 having a plurality of pins that mate with an external host. The number and arrangement of the plurality of pins in the connector 2006 may vary depending on the communication interface between an electronic system 2000 and the external host. In some example embodiments, the electronic system 2000 may communicate with an external host through any of or more of the USB, peripheral component interconnect express (PCI-Express), serial advanced technology attachment (SATA), and M-Phy for universal flash storage (UFS). In some example embodiments, the electronic system 2000 may be powered by an external host through the connector 2006. The electronic system 2000 may further include a power management integrated circuit (PMIC) that distributes power supplied from the external host to the main controller 2002 and the semiconductor package 2003.

According to some example embodiments, the main controller 2002 may write data to or read data from the semiconductor package 2003, and may improve the operating speed of the electronic system 2000.

According to some example embodiments, the DRAM 2004 may be a buffer memory to alleviate the speed difference between the semiconductor package 2003, which is a data storage space, and an external host. The DRAM 2004 included in the electronic system 2000 may alternatively or additionally function as a type of cache memory, and may also provide space for temporary data storage in control operations for the semiconductor package 2003. When the electronic system 2000 includes the DRAM 2004, the main controller 2002 may further include a DRAM controller for controlling the DRAM 2004 in addition to a NAND controller for controlling the semiconductor package 2003.

According to some example embodiments, the semiconductor package 2003 may include a first semiconductor package 2003a and a second semiconductor package 2003b which are spaced apart from each other. Each of the first semiconductor package 2003a and the second semiconductor package 2003b may be a semiconductor package containing a plurality of semiconductor chips 2200. Each of the first semiconductor package 2003a and the second semiconductor package 2003b may include a package substrate 2100 and the semiconductor chips 2200 on the package substrate 2100, bonding layers 2300 arranged on the lower portion surface of each of the semiconductor chips 2200, a connecting structure 2400 electrically connecting the semiconductor chips 2200 and the package substrate 2100, and a molding layer 2500 covering the semiconductor chips 2200 and the connecting structure 2400 on the package substrate 2100.

According to some example embodiments, the package substrate 2100 may be a printed circuit board (PCB) including package upper pads 2130. Each semiconductor chip 2200 may include an input/output pad 2210. The input/output pad 2210 may correspond to the input/output pad 1101 of FIG. 29.

According to some example embodiments, the connecting structure 2400 may be a bonding wire that electrically connects the input/output pads 2210 and the package upper pads 2130. Therefore, in each of the first semiconductor package 2003a and the second semiconductor package 2003b, the semiconductor chips 2200 may be electrically connected to each other by a bonding wire method, and be electrically connected to the package upper pads 2130 of the package substrate 2100. In some example embodiments, in each of the first semiconductor package 2003a and the second semiconductor package 2003b, the semiconductor chips 2200 may be electrically connected to each other by a connecting structure including a through silicon via (TSV) instead of a bonding wire-type connecting structure 2400.

According to some example embodiments, the main controller 2002 and the semiconductor chips 2200 may be included in one package. In some example embodiments, the main controller 2002 and the semiconductor chips 2200 may be mounted on a separate interposer substrate other than the main substrate 2001, and the main controller 2002 and the semiconductor chips 2200 may be connected to each other by wiring formed on the interposer substrate.

According to some example embodiments, the package substrate 2100 may be a PCB. The package substrate 2100 may include a package substrate body part 2120, the package upper pads 2130 disposed on an upper surface of the package substrate body part 2120, lower pads 2125 positioned on or exposed through the lower surface of the package substrate body part 2120, and internal wirings 2135 that electrically connect the upper pads 2130 and the lower pads 2125 within the package substrate body part 2120. The upper pads 2130 may be electrically connected to the connecting structures 2400. The lower pads 2125 may be connected to the wiring patterns 2005 of the main substrate 2001 of the electronic system 2000 as illustrated in FIG. 29 through conductive connection parts 2800.

In an electronic system according to some example embodiments, each of the semiconductor chips 2200 may include a semiconductor memory device as described above with reference to FIG. 1 to FIG. 28. For example, the semiconductor chips 2200 may include the first capacitor structure CAP1 and the second capacitor structure CAP2 arranged in the first block BLK1. Each of the first capacitor structure CAP1 and the second capacitor structure CAP2 may be connected to the first capacitor connection structure 175a and the second capacitor connection structure 175b.

In an electronic system according to some example embodiments, when a signal is input/output to a semiconductor memory device of the semiconductor chips 2200, noise of input/output signals may be alleviated by using the plurality of first capacitor structures CAP1 and the plurality of second capacitor structures CAP2 arranged in the first block BLK1.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

In the above, various example embodiments are described in detail. However, it will be apparent to those with ordinary knowledge in the technical field that scope of rights is not limited thereto, and various modifications and/or variations are possible without departing from the technical spirit as set forth in the claims. Further, the above-described example embodiment may be implemented with some elements deleted, and each example embodiment may be implemented in combination with each other; example embodiments are not necessarily mutually exclusive with one another.

What is claimed is:

1. A semiconductor memory device comprising:
a mold structure comprising a plurality of gate electrodes stacked in a first direction;
a gate electrode cutting pattern separating the mold structure into a plurality of blocks by cutting the plurality of gate electrodes along a plane including the first direction and a second direction intersecting the first direction;
a plurality of first capacitor structures penetrating the mold structure in the first direction, the plurality of first capacitor structures within a first block from among the plurality of blocks;
a plurality of second capacitor structures penetrating the mold structure in the first direction within the first block;
a first capacitor connection structure on the first block and connected to the plurality of first capacitor structures; and
a second capacitor connection structure on the first block and connected to the plurality of second capacitor structures,
wherein a first signal line connected to the first capacitor connection structure and a second signal line connected to the second capacitor connection structure are electrically separated.

2. The semiconductor memory device of claim 1, wherein
each of the plurality of first capacitor structures and the plurality of second capacitor structures define a capacitor hole penetrating the mold structure, and
the semiconductor memory device further comprises,
a dielectric film extending along the capacitor hole, and in contact with the mold structure. and
a conductive film on the dielectric film.

3. The semiconductor memory device of claim 2, wherein each of the plurality of first capacitor structures and the plurality of second capacitor structures further comprises:
a filling film on the conductive film and configured to fill the capacitor hole.

4. The semiconductor memory device of claim 2, wherein
the plurality of first capacitor structures and the plurality of second capacitor structures define a void surrounded by the conductive film within the capacitor hole.

5. The semiconductor memory device of claim 1, further comprising:
an electrode connecting structure penetrating the mold structure in the first direction within the first block, and connected to the plurality of gate electrodes.

6. The semiconductor memory device of claim 5, wherein the electrode connecting structure is between the plurality of first capacitor structures and the plurality of second capacitor structures in the second direction.

7. The semiconductor memory device of claim 1, wherein the first capacitor connection structure and the second capacitor connection structure are spaced apart in the second direction.

8. The semiconductor memory device of claim 1, wherein
a first distance between two adjacent ones of the plurality of first capacitor structures in the second direction and a second distance between two adjacent ones of the plurality of second capacitor structures in the second direction are both shorter than a third distance between one of the plurality of first capacitor structures and one of the plurality of second capacitor structures adjacent to each other in the second direction.

9. The semiconductor memory device of claim 1, further comprising:
a second block spaced apart from the first block with the gate electrode cutting pattern in between, along a third direction intersecting the first direction and the second direction;
a channel structure penetrating the mold structure in the first direction within the second block; and
a bit line on the mold structure within the second block, extending in the third direction, and connected to the channel structure,
wherein the first capacitor connection structure and the second capacitor connection structure are spaced apart from the bit line in the third direction.

10. The semiconductor memory device of claim 9, wherein the first capacitor connection structure and the second capacitor connection structure are at a same height level as the bit line along the first direction.

11. The semiconductor memory device of claim 1, wherein,
in the first block,
the plurality of first capacitor structures are arranged in the second direction, and the plurality of second capacitor structures are arranged in the second direction.

12. The semiconductor memory device of claim 11, wherein the first capacitor connection structure and the second capacitor connection structure are spaced apart in a third direction intersecting the first direction and the second direction.

13. The semiconductor memory device of claim 1, wherein
the plurality of first capacitor structures are configured to receive a first signal,
the plurality of second capacitor structures are configured to receive a second signal,
wherein a level of the first signal and a level of the second signal are different.

14. A semiconductor memory device comprising:
a mold structure comprising a plurality of gate electrodes stacked in a first direction;
a gate electrode cutting pattern extending along a plane defined by the first direction and a second direction intersecting the first direction, and separating the mold structure into a plurality of blocks by cutting the plurality of gate electrodes;
a plurality of first capacitor structures penetrating the mold structure within a first block, the first block being at least one block among the plurality of blocks;
a first electrode connecting structure penetrating the mold structure within the first block and connecting the plurality of gate electrodes;
a plurality of second capacitor structures penetrating the mold structure within a second block spaced apart from the first block with the gate electrode cutting pattern in between, along a third direction intersecting the first direction and the second direction, the second block being at least one block among the plurality of blocks;
a second electrode connecting structure penetrating the mold structure within the second block and connecting the plurality of gate electrodes; and
a capacitor connection structure on the mold structure in the first direction, and connected to the plurality of first capacitor structures and the plurality of second capacitor structures.

15. The semiconductor memory device of claim 14, wherein
the first electrode connecting structure is configured to receive a first signal
the second electrode connecting structure is configured to receive a second signal,
wherein a level of the first signal and a level of the second signal are different.

16. The semiconductor memory device of claim 14, wherein each of the plurality of first capacitor structures and the plurality of second capacitor structures comprises:
a dielectric film in contact with the mold structure; and
a conductive film on the dielectric film, and connected to the capacitor connection structure,
wherein a conductive film of the plurality of first capacitor structures and the plurality of second capacitor structures is electrically floating.

17. The semiconductor memory device of claim 14, further comprising:
a first electrode connection wiring connected to the first electrode connecting structure,
wherein the capacitor connection structure and the first electrode connection wiring are on opposite sides with respect to the mold structure in the first direction.

18. The semiconductor memory device of claim 17, further comprising:
a second electrode connection wiring connected to the second electrode connecting structure,
wherein the first electrode connection wiring and the second electrode connection wiring are on a same side with respect to the mold structure in the first direction.

19. The semiconductor memory device of claim 14, further comprising:
a plurality of first capacitors between the plurality of gate electrodes and the plurality of first capacitor structures within the first block; and
a plurality of second capacitors between the plurality of gate electrodes and the plurality of second capacitor structures within the second block, wherein
the plurality of first capacitors and the plurality of second capacitors are connected in series.

20. A semiconductor memory device comprising:
a cell substrate comprising a first substrate and a second substrate opposite to the first substrate;
a mold structure comprising a plurality of gate electrodes stacked on the first substrate in a first direction perpendicular to the first substrate;
a gate electrode cutting pattern extending along a plane defined by the first direction and a second direction intersecting the first direction, and the gate electrode cutting pattern separating the mold structure into a plurality of blocks by cutting the plurality of gate electrodes;
a plurality of first capacitor structures penetrating the mold structure within a first block, the first block being at least one block among the plurality of blocks;
a first electrode connecting structure penetrating the mold structure within the first block and connecting the plurality of gate electrodes;
a first capacitor connection structure on the first block on the second substrate, and connected to the plurality of first capacitor structures;
a plurality of second capacitor structures penetrating the mold structure within a second block spaced apart from the first block with the gate electrode cutting pattern in between, along a third direction intersecting the first direction and the second direction, the second block being at least one block among the plurality of blocks;
a second electrode connecting structure penetrating the mold structure within the second block and connecting the plurality of gate electrodes; and
a second capacitor connection structure on the second block on the second substrate, and connected to the plurality of second capacitor structures.
